(19) United States
(12) Patent Application Publication
(10) Pub. No.: US 2022/0210316 A1
(43) Pub. Date: Jun. 30, 2022

(54) IMAGE PICKUP APPARATUS OF MEASURING DISTANCE FROM SUBJECT TO IMAGE PICKUP SURFACE OF IMAGE PICKUP DEVICE AND METHOD FOR CONTROLLING THE SAME

(71) Applicant: CANON KABUSHIKI KAISHA, Tokyo (JP)

(72) Inventor: Kohei Okamoto, Yokohama-shi (JP)

(21) Appl. No.: 17/697,295

(22) Filed: Mar. 17, 2022

Related U.S. Application Data
(62) Division of application No. 16/855,233, filed on Apr. 22, 2020.

(30) Foreign Application Priority Data
Apr. 25, 2019 (JP) 2019-084356
Feb. 21, 2020 (JP) 2020-028123

(51) Int. Cl. H04N 5/232; H04N 5/74; H01L 27/146; H04N 5/369; G01S 17/08; H04N 5/225

(52) U.S. Cl. CPC H04N 5/23212; H04N 5/7458; H01L 27/14627; H04N 5/2256; H04N 5/36961; G01S 17/08; H04N 5/2254; H04N 5/36965

(57) ABSTRACT

Provided are image pickup apparatuses capable of measuring a distance in a wide range speedily and accurately, and control methods for the same. In an image pickup apparatus, an image pickup device and a light source are separately disposed in the optical paths branched by a partial reflecting mirror, and the distance from a subject to the image pickup device is calculated using a signal output by the image pickup device. In another image pickup apparatus, an image pickup device includes a light receiver and a light source, and the distance is calculated by a TOF method using a signal output by the light receiver. In another image pickup apparatus, the distance is calculated by a TOF method using a signal output by an image pickup device, and light emission of a light source is controlled on the basis of light emission conditions determined according to image pickup conditions.

### BACKGROUND OF THE INVENTION

### Field of the Invention

The present invention relates to an image pickup apparatus and a method for controlling the same, and more particularly to a technique for performing distance measurement and focus detection during image pickup.

### Description of the Related Art

The image pickup surface phase difference method, which is one of focus detection techniques in a digital camera, obtains three-dimensional data of a subject by indirectly detecting a shift of a focus at each point on the subject. In recent years, techniques that observe information of light field from a subject to obtain three-dimensional information of an object have also been proposed.

A Time of Flight (TOF) method (Hansard et al., ‘Time-of-Flight Cameras Principles, Methods and Applications’, Springer Publishing (2013), hereinafter referred to as Hansard et al.) is one of the techniques used for the purpose of three-dimensional object recognition in a field such as terrain observation and automatic driving. As another one of the techniques, Light Detection And Ranging or LIDAR, which is a technique using the TOF method, is also known. Since the techniques can detect a direct distance to an object, the techniques have been put to practical use in various fields.

A system using a general TOF method has a light source for projecting light to an object and a light receiver, and calculates a propagation time of light that was emitted by the light source, reached an object, and then was received by the light receiver, to estimate a propagation distance of the light, that is, a distance to the object. Such a system may employ an image sensor or the like having an array of photodetectors as the light receiver so as to estimate a distance to each position on the object. That is, it is possible for the system to obtain three-dimensional structure information of the subject, unevenness information of the terrain, and the like.

For example, Japanese Laid-Open Patent Publication (kokai) No. 2018-77143 describes a three-dimensional measurement apparatus including a light source for irradiating an object (subject) with light and an image sensor. For another example, Japanese Laid-Open Patent Publication (kokai) No. 2016-90785 discloses a technique using an image pickup apparatus including an image-forming optical system, a light source, and an image sensor including focus detection pixels. In the technique, distance measurement using the TOF method is made by using pixels not used for focus detection among pixels of the image sensor. This technique allows image pickup apparatuses including an image-forming optical system and an image sensor, to carry out focus detection and distance detection with improved accuracy and further to carry out image pickup of a subject and obtaining three-dimensional information of the subject with high resolution.

In image pickup apparatuses, light enters an image sensor after passing through an image-forming optical system. In image pickup apparatuses in the related art, light is projected from the light source to the subject without passing through the image-forming optical system. It causes shading due to a difference between a region of light projection from the light source to the subject and an image pickup view angle of the image sensor, and a difference between a light projection direction and an image pickup direction. Even in image pickup apparatuses in which light is projected from a light source to a subject through an image-forming optical system, a situation may occur in which the light projection region is different from the image pickup view angle of the image sensor. In particular, in a case where conditions (F value or aperture value, focal length, optical system itself, or the like) of the image-forming optical system are changed, a degree of coincidence between the light projection region and the image pickup view angle changes, and there is a concern that projection efficiency of light from the light source decreases.

In addition, image pickup apparatuses in the related art are broadly classified into a group of techniques that measures a wide range of distance at high speed by simultaneously projecting a wide light projection region with a divergent light source and a group of techniques that measures a distance by performing scanning with a laser beam having high directivity. In the techniques of the former group, the light intensity per unit solid angle is rapidly attenuated as the distance from the light source to the object increases due to the divergence of the light from the light source. Therefore, the techniques of the former group are not suitable for distance measurement from a medium distance to a long distance. Meanwhile, in the techniques of the latter group, since the light intensity per unit solid angle is basically hard to be attenuated, it is possible to measure a distance from a medium distance to a long distance. However, the techniques need the light projection region to be two-dimensionally scanned and there is a problem in that it takes time until the distance measurement is completed.

### SUMMARY OF THE INVENTION

The present invention provides image pickup apparatuses capable of measuring a distance to a subject in a wide range at high speed with high accuracy and methods for controlling the same.

Accordingly, a first aspect of the present invention provides an image pickup apparatus comprising: an image-forming optical system; an image pickup device comprising a microlens array; and a light source comprising another microlens array, where the light source is configured to emit pulsed light through the another microlens array. The image pickup apparatus further comprises a partial reflecting mirror disposed in the image-forming optical system, and the partial reflecting mirror is configured to project light emitted by the light source to a subject and to guide light from the subject to the image pickup device. The image pickup apparatus further comprises: at least one memory; and at least one processor configured to execute instructions stored in the at least one memory to calculate a distance from the subject to an image pickup surface of the image pickup device using a signal output by the image pickup device receiving light emitted by the light source and reflected on the subject. The partial reflecting mirror is disposed to make an angle between an optical axis of the image-forming optical system and a normal line to a surface of the partial reflecting mirror larger than 0° and smaller than 90°. The image pickup device and the light source are separately disposed at a position where light from the subject travels after reflected on the partial reflecting mirror and a position where light from the subject travels after passing through the partial reflecting mirror so that a pupil distance of the light source comprising the another microlens array and a pupil distance of the image pickup device comprising the microlens array coincide with each other and the image pickup device and the light source are conjugate with each other with respect to the subject via the image-forming optical system.

Accordingly, a second aspect of the present invention provides an image pickup apparatus comprising: an image-forming optical system; and an image pickup device. The image pickup device comprises a light receiver and a light source, where the light receiver is configured to receive light from a subject through the image-forming optical system, and the light source is configured to emit pulsed light toward the subject. The image pickup apparatus further comprises: at least one memory; and at least one processor configured to execute instructions stored in the at least one memory to calculate, by a TOF method, a distance from the subject to an image pickup surface of the image pickup device using a signal output by the light receiver receiving light emitted by the light source and reflected on the subject.

Accordingly, a third aspect of the present invention provides an image pickup apparatus comprising: an image pickup device; a light source configured to emit pulsed light to a subject; an image-forming optical system configured to guide light from the subject to the image pickup device; at least one memory; and at least one processor. The at least one processor is configured to execute instructions stored in the at least one memory to: calculate, by a TOF method, a distance from the subject to an image pickup surface of the image pickup device using a signal output by the image pickup device receiving light emitted by the light source and reflected on the subject; determine a condition for light emission of the light source according to a condition for pickup of an image of the subject; and control light emission of the light source to the subject on a basis of the determined condition for light emission.

Accordingly, a fourth aspect of the present invention provides a method for controlling an image pickup apparatus. The method comprises: focusing an image-forming optical system on a predetermined subject; and projecting light in an infrared wavelength band from a light source, through a microlens array, to a partial reflecting mirror disposed in the image-forming optical system. The method further comprises, upon the light in an infrared wavelength band being reflected on the partial reflecting mirror and projected to the subject through the image-forming optical system, measuring a distance from the subject to an image pickup surface of an image pickup device by a TOF method, using a signal output by the image pickup device receiving light reflected on the subject and traveling through the image-forming optical system. The method further comprises: generating a distance map from a result of measurement of the distance by the TOF method; performing image pickup using a signal output from the image pickup device receiving light in a visible light wavelength band, traveling from the subject and entering the image-forming optical system; and storing image data generated by the distance map and the image pickup in a storage unit. In the image-forming optical system, the partial reflecting mirror is disposed to make an angle between an optical axis of the image-forming optical system and a normal line to a surface of the partial reflecting mirror larger than 0° and smaller than 90°. The light source and the image pickup device are separately disposed at a position where light from the subject travels after reflected on the partial reflecting mirror and a position where light from the subject travels after passing through the partial reflecting mirror so that a pupil distance of the light source comprising microlenses and a pupil distance of the image pickup device comprising a plurality pixels and microlenses disposed for the respective pixels coincide with each other and that the image pickup device and the light source are conjugate with each other with respect to the subject via the image-forming optical system.

Accordingly, a fifth aspect of the present invention provides a method for controlling an image pickup apparatus. The method comprises: projecting light from a light source included in an image pickup device to a subject; and upon the light being projected from the light source and reflected on the subject, calculating a distance from the subject to an image pickup surface of the image pickup device by a TOF method, using a signal output by a first light receiver included in the image pickup device, receiving the light reflected on the subject. The method further comprises: generating a distance map from a result of calculation of the distance by the TOF method; performing image pickup using a signal output from a second light receiver included in the image pickup device, receiving light in a visible light wavelength band, traveling from the subject to enter the image pickup device; and storing image data generated by the distance map and the image pickup in a storage unit.

Accordingly, a sixth aspect of the present invention provides a method for controlling an image pickup apparatus. The method comprises: projecting light from a light source to a subject; and upon the light being projected from the light source and reflected on the subject, calculating a distance from the subject to an image pickup surface of an image pickup device by a TOF method, using a signal output by the image pickup device receiving the light reflected on the subject. The method further comprises: generating a distance map from a result of calculation of the distance by the TOF method; adjusting an image-forming optical system by using a result of calculation of the distance, to focus the image-forming optical system on a partially selected region of the subject; performing image pickup on the subject with the image pickup device, with the image-forming optical system focused on the partially selected region; and storing image data generated by the distance map and the image pickup in a storage unit.

According to the present invention, it is possible to provide image pickup apparatuses capable of measuring a distance to a subject in a wide range at high speed with high accuracy and methods for controlling such an image pickup apparatus.

Further features of the present invention will become apparent from the following description of exemplary embodiments with reference to the attached drawings.

### BRIEF DESCRIPTION OF THE DRAWINGS

FIG. 1 is a block diagram showing a schematic configuration of an image pickup apparatus according to a first embodiment.

FIG. 2 is a side view explaining a schematic configuration of a light source of the image pickup apparatus in FIG. 1.

FIG. 3 is a diagram explaining a state in which light emitted by the light source in FIG. 2 reaches a subject.

FIGS. 4A and 4B are plan views explaining a schematic configuration of an image pickup device of the image pickup apparatus in FIG. 1.

FIGS. 5A and 5B are cross-sectional views explaining a schematic configuration of the image pickup device of the image pickup apparatus in FIG. 1.

FIG. 6 is a flowchart showing an image pickup sequence in the image pickup apparatus in FIG. 1.

FIG. 7 is a diagram explaining a relationship between an optical path of a laser beam emitted by the light source in FIG. 2 and light incident on the image pickup device.

FIG. 8 is a block diagram showing a schematic configuration of an image pickup apparatus according to a second embodiment.

FIG. 9 is a diagram explaining a structure of each pixel constituting an image pickup device of the image pickup apparatus in FIG. 8.

FIG. 10 is a flowchart of an image pickup sequence in the image pickup apparatus in FIG. 8.

FIG. 11 is a block diagram showing a schematic configuration of an image pickup apparatus according to a third embodiment.

FIGS. 12A and 12B are diagrams explaining a relationship between a mirror operation and a light flux in the image pickup apparatus in FIG. 11.

FIG. 13 is a block diagram showing a schematic configuration of an image pickup apparatus according to a fourth embodiment.

FIG. 14 is a diagram explaining a configuration of an image pickup device of the image pickup apparatus in FIG. 13.

FIG. 15 is a diagram explaining an array of light receivers constituting the image pickup device in FIG. 14.

FIG. 16 is a diagram explaining a relationship between an image pickup view angle of the image pickup device in FIG. 14 and a light projection range of a light emitter.

FIG. 17 is a cross-sectional view showing a schematic configuration of a light receiving element (pixel) of the image pickup device in FIG. 14.

FIG. 18 is a diagram showing a relationship between a pixel structure in FIG. 17 and an exit pupil plane of an image-forming optical system.

FIG. 19 is a diagram explaining a signal intensity output by a sub photoelectric converter of the pixel in FIG. 17.

FIG. 20 is a flowchart explaining an image pickup sequence in the image pickup apparatus in FIG. 13.

FIG. 21 is a block diagram showing a schematic configuration of an image pickup apparatus according to a fifth embodiment.

FIGS. 22A and 22B are diagrams explaining a schematic configuration of a light source of the image pickup apparatus in FIG. 21 and emission light.

FIGS. 23A to 23C are diagrams explaining examples of light emitted by the light source in FIG. 22A and a light projection region.

FIG. 24 is a diagram explaining a distance measuring method by a TOF method in the image pickup apparatus in FIG. 21.

FIG. 25 is a block diagram showing a schematic configuration of an image pickup apparatus according to a sixth embodiment.

FIG. 26 is a flowchart of an image pickup sequence in the image pickup apparatus in FIG. 25.

### DESCRIPTION OF THE EMBODIMENTS

The present invention will now be described in detail below with reference to the accompanying drawings showing embodiments thereof.

Hereinafter, embodiments of the present invention will be described in detail with reference to the accompanying drawings.

### First Embodiment

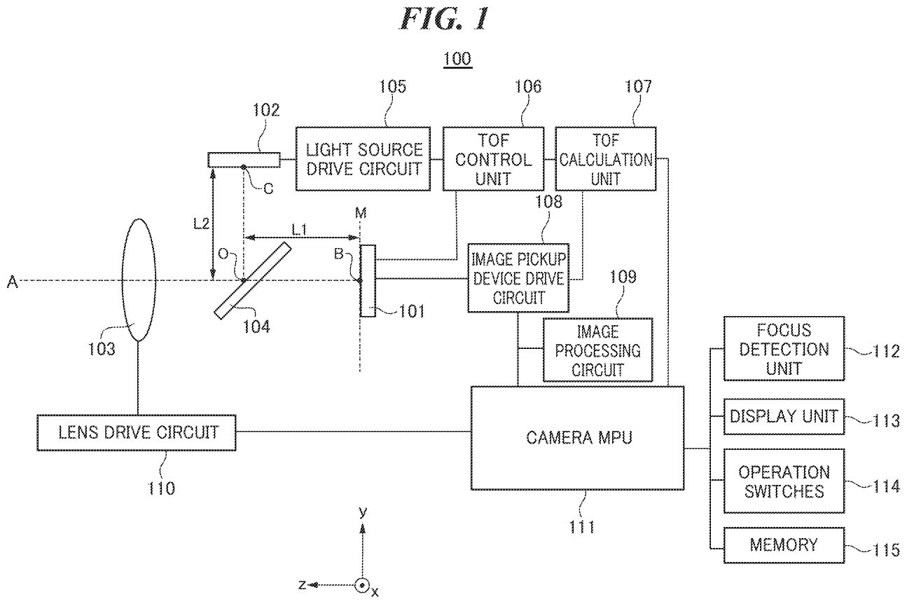

FIG. 1 is a block diagram showing a schematic configuration of an image pickup apparatus 100 according to a first embodiment of the present invention. The image pickup apparatus 100 includes an image-forming optical system 103, an image pickup device 101, a light source 102, and a partial reflecting mirror 104, and these constitute a main optical system of the image pickup apparatus 100. The image pickup apparatus 100 also includes a light source drive circuit 105, a TOF control unit 106, a TOF calculation unit 107, an image pickup device drive circuit 108, an image processing circuit 109, a lens drive circuit 110, and a camera MPU 111. The image pickup apparatus 100 further includes a focus detection unit 112, a display unit 113, operation switches 114, and a memory 115.

The camera MPU 111 performs overall control of the image pickup apparatus 100. The operation switches 114 receive various instructions from a user, and transmit the received instructions to the camera MPU 111. The display unit 113 displays a subject image or various setting conditions for the image pickup apparatus 100. It should be noted that the display unit 113 includes a touch panel. The memory 115 includes a ROM which stores various information necessary for controlling the image pickup apparatus 100, and a storage medium such as an SD card which stores image data or the like. The focus detection unit 112 includes an image pickup sensor, and performs focus detection on a subject by a contrast AF method based on an image pickup signal.

In FIG. 1, the broken line AOB represents the central optical axis of the image-forming optical system 103. A subject (not shown) is located on the A side of the apparatus, and the broken line AOB connects the subject, the partial reflecting mirror 104, and the image pickup device 101 to each other. Meanwhile, the broken line AOC is a line connecting the subject, the partial reflecting mirror 104, and the light source 102 to each other, and represents the central optical axis of an optical system located on the line. In the image pickup apparatus 100, the image pickup device 101 and the light source 102 are disposed at spatially different positions, more specifically, are separately disposed at a position where light from the subject travels after reflected on the partial reflecting mirror 104 and a position where light from the subject travels after passing through the partial reflecting mirror 104 so that the image pickup device 101 and the light source 102 are conjugate with each other with respect to the subject via the image-forming optical system 103. Therefore, the apparatus is configured so that the distance L1 (distance between OB) between the partial reflecting mirror 104 and the image pickup surface M of the image pickup device 101 and the distance L2 (distance between OC) between the partial reflecting mirror 104 and the light source 102 are substantially equal to each other (L1=L2). As shown in FIG. 1, it should be noted that the x-axis, the y-axis, and the z-axis which are orthogonal to each other are defined. The z-axis is an axis parallel to the optical axis AO, and the y-axis is an axis parallel to the optical axis OC. The image pickup surface M of the image pickup device 101 is orthogonal to the z-axis.

The image-forming optical system 103 may have a known configuration generally used in a digital camera. That is, the image-forming optical system 103 may be a lens barrel (interchangeable lens) detachable from a lens-interchangeable camera such as a single-lens reflex camera, or a collapsible lens barrel or a fixed lens barrel provided in an image pickup apparatus body on which the image pickup device 101 is mounted. Further, the image-forming optical system 103 may be capable of changing an F value by an aperture (not shown) and/or changing a focal length by driving a zoom lens. Further, the image-forming optical system 103 may be configured so as to change in the intensity of transmission light by an ND filter (not shown), a polarization state by a polarizing filter, or the like. Lenses and an aperture of the image-forming optical system 103 are driven by the lens drive circuit 110 under a control of the camera MPU 111.

The partial reflecting mirror 104 is disposed at a position to split light from the subject into light traveling to the image pickup device 101 and light traveling to the light source 102. In other words, the partial reflecting mirror 104 is disposed in the image-forming optical system 103, at a position to project light emitted by light source 102 to the subject and to guide light from the subject to the image pickup device 101. The partial reflecting mirror 104 is configured so that an angle between a normal vector of a reflecting surface of the partial reflecting mirror 104 and the optical axis AO of the image-forming optical system is larger than 0° and smaller than 90°. The partial reflecting mirror 104 is a multilayer mirror in which thin films of silicon oxide (SiO₂) and thin films of niobium oxide (Nb₂O₅) are layered on one surface, which faces the point O, of a pellicle film made of resin, and an antireflection film (AR coat) is applied to the other surface of the pellicle film.

A ratio between a transmittance and a reflectance of the partial reflecting mirror 104 is approximately six to four. The transmittance is set to be slightly higher than the reflectance, which enables the image pickup device 101 to efficiently receive light traveling from the subject through the image-forming optical system 103 and entering the image pickup device 101. The material of the substrate of the partial reflecting mirror 104 is not limited to resin, and various transparent materials such as glass can be used. The configuration of the coating of the mirror, having the partial reflecting function is not limited to the above-described configuration.

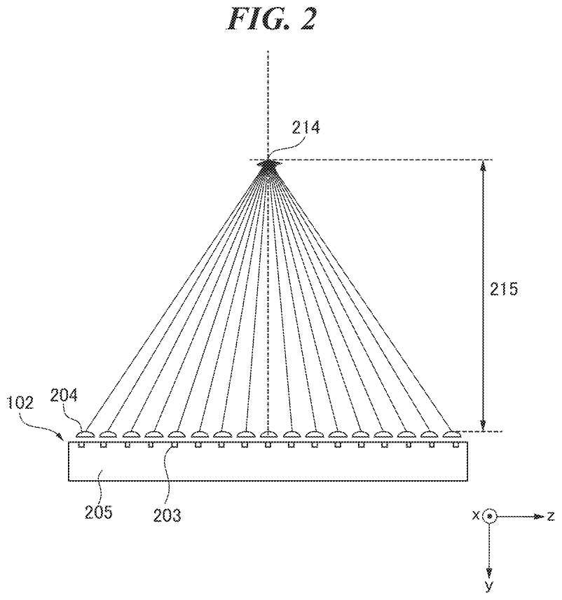

FIG. 2 is a side view showing a schematic configuration of the light source 102. In the present embodiment, the light source 102 includes a plurality of light emission parts 203 formed in a two-dimensional array on a gallium arsenide (GaAs) based semiconductor substrate 205. Microlenses 204 are disposed above the respective light emission parts 203 in a two-dimensional array, and thus, a microlens array is formed. Each microlens 204 collimates (or makes the divergence angle approach 0°) the light from the corresponding light emission part 203 or suppresses divergence of the light.

In the light source 102, surface emitting lasers (Vertical Cavity Surface Emitting Lasers) with a center emission wavelength of about 800 nm are used as the light emission parts 203. A wavelength being out of a visible light wavelength band that is used for pickup of a subject image, is used for light to be emitted by the light source 102, which enables an easy distinction between signals of distance measurement using the TOF method and signals of image pickup.

The light emission parts 203 are not limited to the above-described configuration, and for example, stripe lasers, light emitting diodes (LEDs), quantum dot elements, and organic EL elements can be used. Since many types of minute light emitter including surface emitting lasers, emit divergent light, the microlenses 204 are disposed to suppress the divergence of divergent light from the light emission parts 203. The light source 102 may have a single light emission part (single light source), but requires a microlens array.

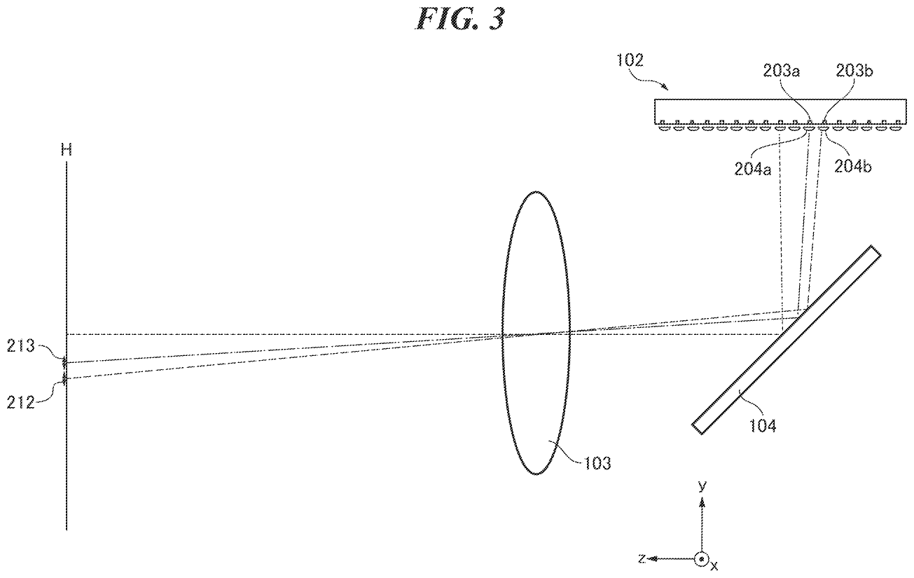

FIG. 3 is a diagram explaining a state in which light emitted by the light source 102 reaches the subject. Light from a light emission part 203a located near the center of a light emitting surface of the light source 102 and light from a light emission part 203b adjacent thereto reach the subject H with the divergence of the light controlled by the corresponding microlenses 204a and 204b. In this light source 102, the distance between the light emission parts 203a and 203b and the microlenses 204a and 204b are defined so that a region 212 to which the light from the light emission part 203a reaches and a region 213 to which the light from the light emission part 203b reaches do not greatly overlap with each other and are not greatly separated from each other. The similar configuration is made for the other light emission parts 203, and thus, such configuration enables even projection of light from the light source 102 onto a required region on the subject at a predetermined distance.

It should be noted that the light source 102 is not limited to the configuration described with reference to FIG. 2. For example, there may be provided the configuration so as to further collimate light from the light emission parts, and thus, it enables the light source 102 to project light having sufficient intensity even when the subject distance is long. Moreover, in such a configuration, even in an out-of-focus state, light from the light source is hardly blurred on the image pickup surface M, and thus, the distance measurement can be performed with high accuracy. In order to achieve projection of light by the light source 102 with high efficiency in consideration of a variation in the light emission parts 203 or the like in the manufacturing of the light source 102, it is also desirable to define the distance between the light emission parts 203a and 203b and the microlenses 204a and 204b so that the light projection region exists slightly inside a subject region corresponding to the image pickup view angle. That is, the light source 102 is desirably configured such that the light projection region of light emitted by the light source 102 to the subject becomes narrower than the subject region corresponding to the image pickup view angle of the image pickup device 101.

In the present embodiment, the light source 102 is configured such that each of the positions of the microlenses 204 corresponding to respective light emission parts 203 is largely eccentric toward the center of the entire light emitting region of the light source 102 as the distance of each of the microlenses 204 from the center increases. Such a configuration changes the propagation direction of light emitted by each light emission part 203 toward the optical axis of the image-forming optical system, which makes light from all light emission parts 203 intersect at almost one point on the optical axis. In the present embodiment, this point is called a light source pupil 214, and a distance from the light emitting surface to the light source pupil is called a light source pupil distance 215.

The light source 102 is configured so that a light source pupil 214 coincides with a sensor pupil, which will be described later, of the image pickup device 101. Such a configuration keeps the light projection region constant in comparison with the subject region corresponding to the image pickup surface M of the image pickup device 10, and thus, the distance measurement can be performed with high light projection efficiency. It should be noted that the light source 102 may have a single light emission part, and in this case, the above-described light source pupil is not defined, and it can be handled as if the light source pupil and the sensor pupil coincide with each other.

Meanwhile, in a case where the sizes of the image pickup surface M of the image pickup device 101 and the entire light emitting region of the light source 102 are different from each other, the light source pupil distance and the sensor pupil distance may be adjusted to be different so that the image pickup view angle and the light projection region approximately coincide with each other. In the present embodiment, the sizes of the image pickup surface M of the image pickup device 101 and the entire light emitting region of the light source 102 are the same as each other. In other words, the sizes and shapes of an effective pixel region on the image pickup device 101 and a region of the light source 102 where the light emission parts 203 are disposed coincide with each other. Accordingly, the sensor pupil distance and the light source pupil distance coincide with each other.

It should be noted that a slight difference between the sensor pupil distance and the light source pupil distance due to a manufacturing process or an assembly error of the image pickup apparatus 100 can be tolerated. In the description of the present embodiment, expressions “same” and “coincide with” are not strictly interpreted, and have a certain range which allows intentional shift, an assembly error, or the like as long as desired performance is obtained.

When the focal length of the image-forming optical system 103 is short or the F value is large, the amount of light from the light source 102 per unit area on a plane at a certain distance decreases. Therefore, the image pickup apparatus 100 may have the configuration so as to change the intensity of light emitted by the light source 102 in accordance with a change in the focal length or the F value. By transmitting information on the focal length and the F value of the image-forming optical system 103 to the light source drive circuit 105 from the image-forming optical system 103, the lens drive circuit 110, or the camera MPU 111 as needed, it is possible to perform the distance measurement with an appropriate amount of light.

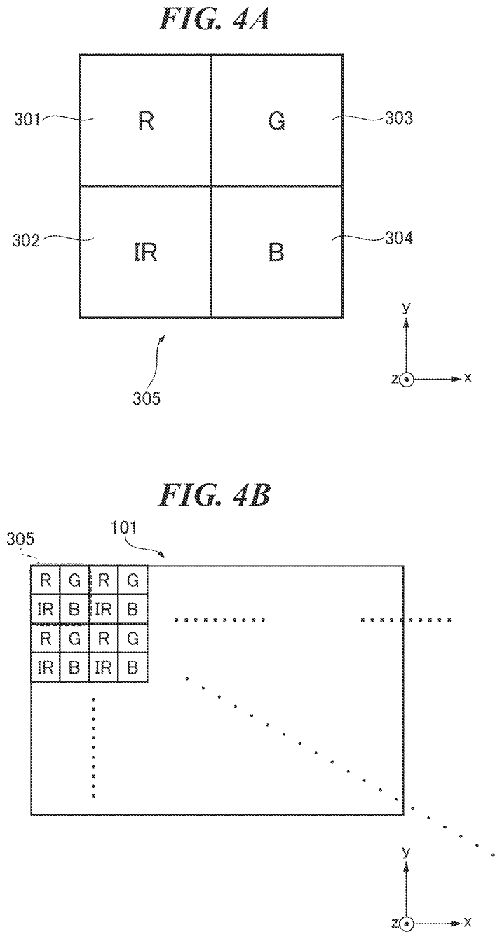

In the image pickup device 101, the effective pixel region has a horizontal size of 22.32 mm, a vertical size of 14.88 mm, an effective pixel number of 6000 in the horizontal direction, and an effective pixel number of 4000 in the vertical direction. FIG. 4A is a plan view showing a basic pixel group 305 including pixels in two rows and two columns, which is a part of a plurality of image pickup pixels arranged on the image pickup surface M of the image pickup device 101. The basic pixel group 305 includes a pixel 301 having a spectral sensitivity in a wavelength band corresponding to red, a pixel 304 having a spectral sensitivity in a wavelength band corresponding to blue, a pixel 303 having a spectral sensitivity in a wavelength band corresponding to green, and a pixel 302 having spectral sensitivity in a near-infrared light wavelength band. It should be noted that the basic configuration of the pixels 301 to 304 forming the basic pixel group 305 is the same except for the color filters.

FIG. 4B is a plan view showing the arrangement of the basic pixel groups 305 in the image pickup device 101. In the image pickup device 101, the basic pixel groups 305 are arranged in a two-dimensional array in the x direction and the y direction.

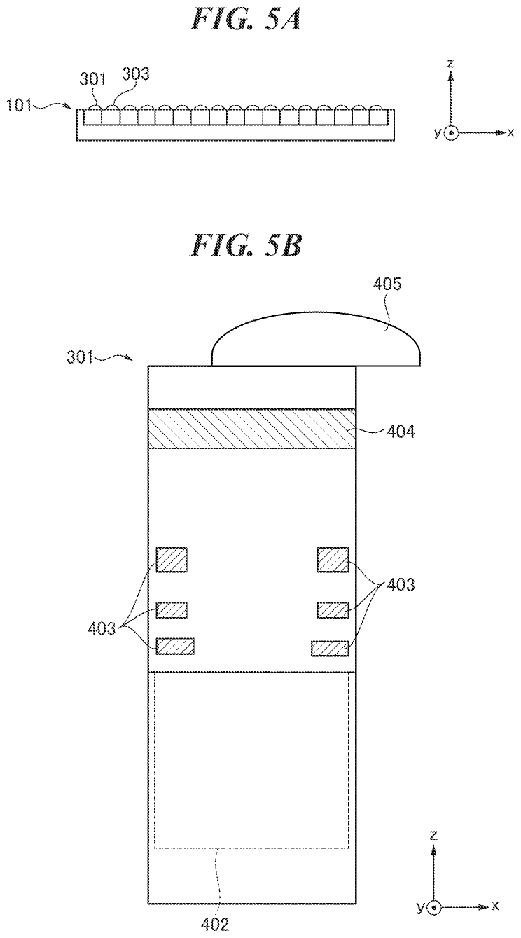

FIG. 5A is a diagram showing a schematic configuration of the image pickup device 101 in a ZX cross section in a row of RG in FIG. 4B. FIG. 5B is a cross-sectional view showing a schematic configuration of the pixel 301. The pixel 301 includes a photoelectric converter 402, wiring parts 403, a color filter 404, and a microlens 405 which are provided on a surface layer of a silicon (Si) substrate. In each pixel of the image pickup device 101, the microlens 405 is disposed eccentrically to the center of the image pickup surface M, the microlens 405 is more eccentric as the pixel of a peripheral portion of the image pickup surface M, which determines the sensor pupil and the sensor pupil distance. As described above, the pixels 301 are optically different from the other pixels (pixels 302 to 304) in only the color filters 404.

The TOF control unit 106 controls driving of the light source drive circuit 105 according to a command from the camera MPU 111 when performing the distance measurement by the TOF method. The TOF calculation unit 107 calculates a distance from a predetermined point on the subject to the image pickup surface M of the image pickup device 111 using a signal output by the pixel 302 of the image pickup device 101. The image pickup device drive circuit 108 controls driving of the image pickup device 111. The image processing circuit 109 generates image data from signals output by the pixels 301, 303, and 304 of the image pickup device 111.

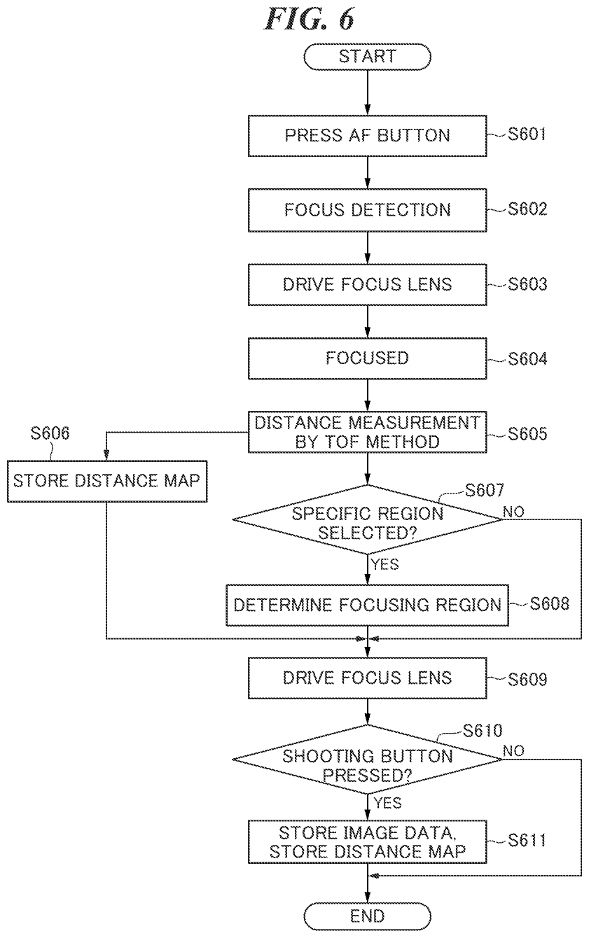

Next, an image pickup sequence performed by the image pickup apparatus 100 will be described. FIG. 6 is a flowchart showing the image pickup sequence in the image pickup apparatus 100. Each processing (step) indicated by a symbol S in FIG. 6 is realized by the camera MPU 111 executing a predetermined program and totally controlling the operation of each unit of the image pickup apparatus 100.

In S601, the camera MPU 111 detects that an AF button is pressed. It should be noted that the pressing of the AF button indicates a state where a so-called release button constituted by a two-stage switch is half-pressed, and thus, start of an AF operation is instructed to the camera MPU 111. In S602, the camera MPU 111 controls the focus detection unit 112 to perform focus detection processing by the contrast AF method. In S603, the camera MPU 111 drives the lens drive circuit 110 based on the focus detection signal from the focus detection unit 112 to move the focus lens in the optical axis direction. Accordingly, in S604, the MPU 111 can bring the image-forming optical system 103 into a state in which the subject is focused (in focus).

In S605, the camera MPU 111 drives the light source 102 by driving the light source drive circuit 105 through the TOF control unit 106. As a result, a periodic rectangular pulsed laser beam with a center wavelength of 800 nm is output by the light source 102.

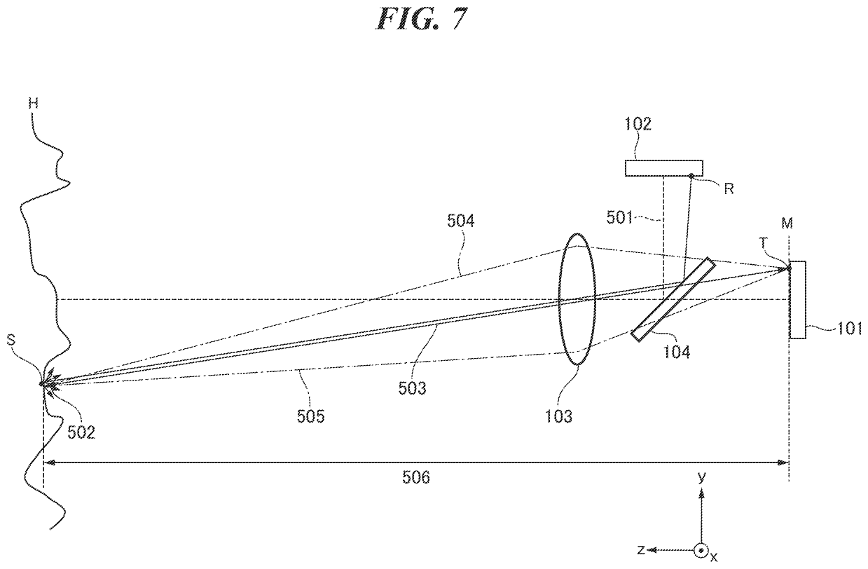

FIG. 7 is a diagram for explaining a relationship between an optical path of the laser beam emitted by the light source 102 and the light incident on the image pickup device 101. Light emitted by the light emission part 203 at a certain point R on the light emitting surface of the light source 102 (herein, the optical center of the emitted light is indicated by a broken line 501) is reflected by the partial reflecting mirror 104, passes through the image-forming optical system 103, and reaches a predetermined point S on the subject H. Since the light emitted by the light emission part 203 has a width within a range satisfying the above-described conditions, scattered light 502 including reflection of the emitted light is made at the point S on the subject H. The scattered light 502 passes through an area (the area indicated by broken lines 504 and 505 centered on a solid line 503) where light passing through an opening of the image-forming optical system 103 can pass through, and is formed into an image at a predetermined point T on the image pickup device 101 through the partial reflecting mirror 104.

Since the light source 102 and the image pickup device 101 are disposed in a conjugate relationship through the image-forming optical system 103, a position of the point R on the light emitting surface of the light source 102 and the point T on the image pickup surface M of the image pickup device 101 coincide with each other. Moreover, as described above, in the present embodiment, since the image pickup surface M of the image pickup device 101 and the entire light emitting region of the light source 102 have the same shape and the same size as each other, there is less wasted light which is projected outside the image pickup view angle, and thus, it is possible to increase light projection efficiency.

The light receiving timing of IR pixels (pixels 302) of the image pickup device 101 is that determined by a periodic rectangular pulse, and the image pickup device 101 thereby detects a time lag between a pulsed laser light from the light source 102 and the corresponding received reflected light and generates a detection signal or a signal related thereto. Then, the TOF calculation unit 107 calculates a distance 506 between the point S on the subject H and the image pickup surface M from the generated signal. It should be noted that a method of detecting pulsed light emitted by the light source 102 and the reflected light thereof, and a calculation of signals can use a known TOF method, and for example, can use a phase detection method of Hansard et al. described above. It should be noted that various techniques have been studied and proposed for the TOF method, and these techniques can be used in the present embodiment, and it is not necessary to use a specific technique in a limited manner.

When the distance measurement by the TOF method is performed in S605, in S606, the camera MPU 111 generates a distance map of the subject based on a result of the distance measurement by the TOF method in S605, and stores the generated distance map in an internal memory of the camera MPU 111. After that, the camera MPU 111 advances the processing to S609. Meanwhile, during the execution of S605, a user can operate the touch panel provided on the display unit 113 of the image pickup apparatus 100 to select an arbitrary region in the image as a focusing region (AF region). Therefore, in S607, the camera MPU 111 determines whether or not a specific region in the image is selected. In a case where the camera MPU 111 determines that the specific region is not selected (NO in S607), the processing proceeds to S609. In a case where the camera MPU 111 determines that the specific region is selected (YES in S607), the processing proceeds to S608. In S608, the camera MPU 111 determines the region selected in S607 as the focusing region.

In S609, the camera MPU 111 drives the focus lens based on the distance map created and stored in S606 and the focusing region determined in S607, and performs focus adjustment (focusing) on the focusing region. By driving the focus lens using absolute distance information to the subject obtained by the TOF method in this way, it is possible to perform the focus adjustment with high speed.

In S610 after the focus adjustment, the camera MPU 111 determines whether or not a shooting button is pressed. It should be noted that the pressing of the shooting button indicates a state where a so-called release button configured by a two-stage switch is fully pressed, and thus, start of the shooting is instructed to the camera MPU 111. In a case where the camera MPU 111 determines that the shooting button is not pressed (NO in S610), in the present embodiment, the camera MPU 111 determines that the user stops the shooting, and thus, the present processing ends. Meanwhile, in a case where the camera MPU 111 determines that the shooting button is pressed (YES in S610), the processing proceeds to S611.

In S611, the camera MPU 111 stores image data of a picked-up image and the distance map created in S606 in a storage medium such as an SD card included in the memory 115, and thus, the present processing ends. It should be noted that the image data is generated using signals from R, G, B pixels (pixels 301, 303, 304) of the image pickup device 101, and the distance map is generated using signals from the IR pixels (pixels 302).

It should be noted that the order of each processing in the flowchart of FIG. 6 can be changed within a range that does not hinder the image pickup. For example, in the above-described the sequence, the distance measurement by the TOF method is performed after the focus detection by the contrast AF method is performed. However, the focus detection may be performed after the distance measurement by the TOF method is performed.

### Second Embodiment

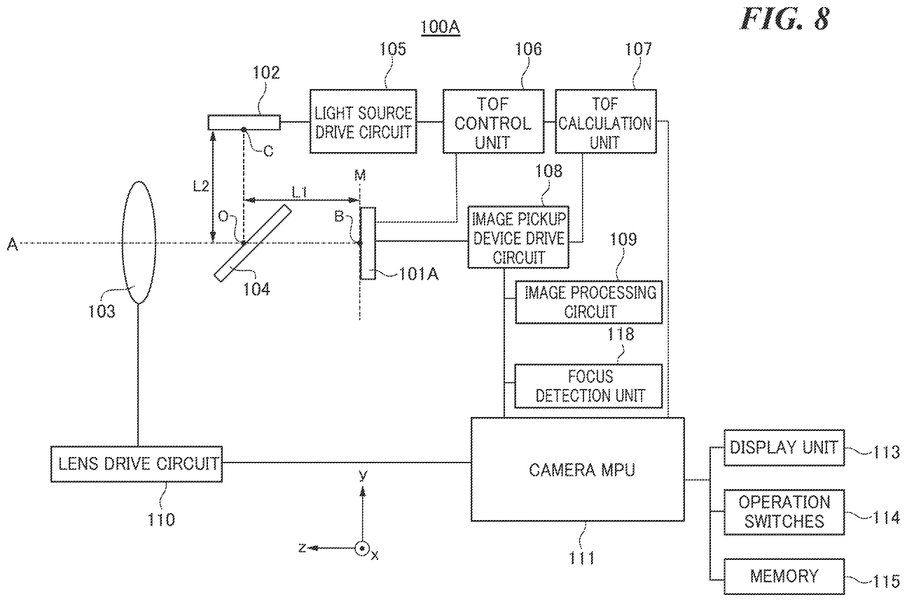

FIG. 8 is a block diagram showing a schematic configuration of an image pickup apparatus 100A according to the second embodiment. Among components of the image pickup apparatus 100A, the same reference numerals are assigned to the same components as those of the image pickup apparatus 100 according to the first embodiment, and descriptions thereof are omitted.

The image pickup apparatus 100 according to the first embodiment includes a focus detection unit 112 having an image pickup sensor that performs focus adjustment by a contrast AF method. Meanwhile, the image pickup device according to the second embodiment is different from the image pickup apparatus 100 according to the first embodiment in that the image pickup device according to the second embodiment includes an image pickup device 101A which enables focus detection by an image pickup surface phase difference method, and includes a focus detection unit 118 associated therewith.

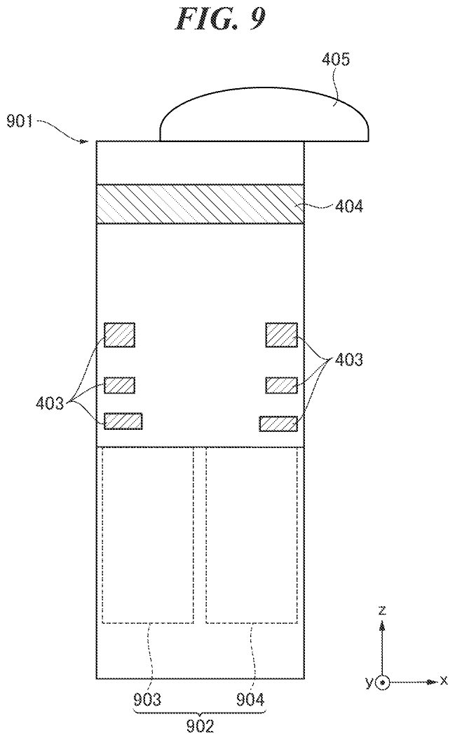

FIG. 9 is a view for explaining the structure of each of pixels 901 constituting the image pickup device 101A on the same ZX cross section as FIG. 5B. Among the components of the pixel 901, the same reference numerals are assigned to the same components as those of the pixel 301 shown in FIG. 5B and descriptions thereof are omitted. It should be noted that the arrangement of R, G, B, and IR pixels in the image pickup device 101A are the same as that of the image pickup device 101, and thus, illustrations and descriptions thereof are omitted.

The pixel 901 is different from the pixel 301 of FIG. 5B in that a structure of a photoelectric converter 902 is different from the structure of the photoelectric converter 402. However, other configurations are the same as those of the pixel 301. Descriptions of configurations common to the pixel 301 are omitted. The photoelectric converter 902 has a first photoelectric converter 903 and a second photoelectric converter 904 which are given by substantially equally dividing the photoelectric converter 902 in the x direction. The focus detection unit 118 performs focus detection by an image pickup surface phase difference method using an image obtained by the first photoelectric converter 903 and an image obtained by the second photoelectric converter 904. Since the image pickup surface phase difference method is well known, a detailed description thereof is omitted here. It should be noted that in the image pickup surface phase difference method, since a shift amount (defocus amount) from the in-focus state is calculated, it is not necessary to perform focus adjustment while driving the focus lens as in the case of the contrast AF method. Accordingly, it is possible to perform the focus adjustment at high speed.

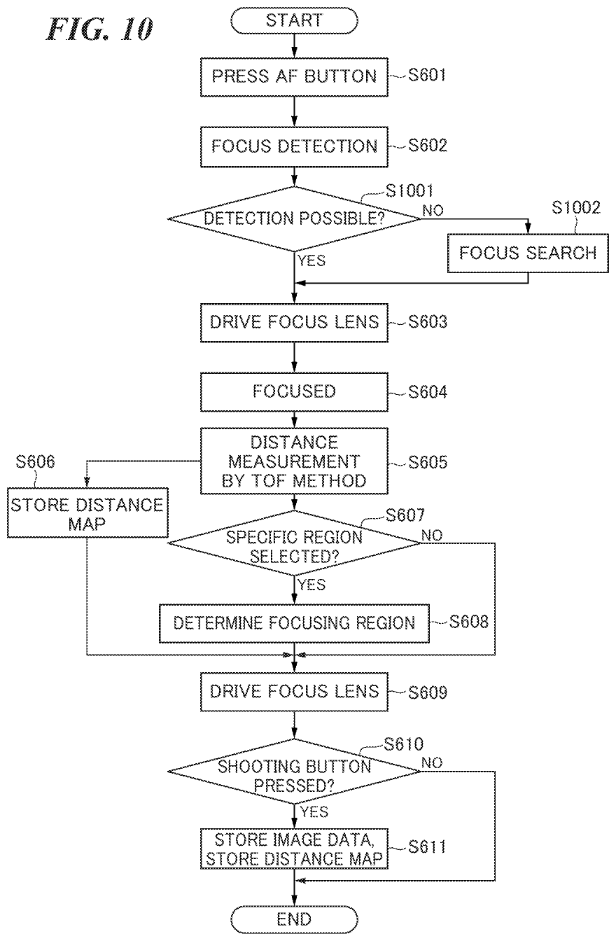

FIG. 10 is a flowchart showing an image pickup sequence in image pickup apparatus 100A. Each processing (step) indicated by a symbol S in FIG. 10 is realized by the camera MPU 111 executing a predetermined program and totally controlling the operation of each unit of the image pickup apparatus 100A. It should be noted that among the processes shown in the flowchart of FIG. 10, the same S numbers are assigned to the same processes as those in the flowchart of FIG. 6, and description thereof will be omitted.

In the image pickup sequence in the image pickup apparatus 100A, the camera MPU 111 controls the focus detection unit 118 to perform focus detection by the image pickup surface phase difference method in the focus detection in S602. After the focus detection starts, the camera MPU 111 determines whether or not the focus detection is possible in S1001. In a case where the camera MPU 111 determines that the focus detection is possible (YES in S1001), the processing proceeds to S603. In a case where the camera MPU 111 determines that the focus detection is not possible (NO in S1001), the processing proceeds to S1002. The case where the determination in S1001 is “NO” is a case where it is difficult to detect the defocus amount by the image pickup surface phase difference method. Therefore, in S1002, the camera MPU 111 performs a search processing that drives the focus lens until the defocus amount can be detected, and when the defocus amount can be detected, the processing proceeds to S603. The processing after S603 is the same as the image pickup sequence shown in FIG. 6. It should be noted that in S603 of the flowchart in FIG. 10, the focus lens is driven based on a focus detection result by the focus detection unit 118.

It should be noted that the image pickup sequence in the image pickup apparatus 100A is not limited to the flow in FIG. 10. For example, even after the camera MPU 111 performs the distance measurement by the TOF method, the camera MPU 111 may estimate the shift amount from the in-focus state based on the created distance map, and thereafter, may perform high-precision focus adjustment by the image pickup surface phase difference method. In addition, creation of the distance map of the subject based on the signals of the IR pixels receiving IR light by the TOF method and acquisition of the defocus amount by the focus detection based on the signals from the photoelectric converters 902 of the respective R, G, and B pixels 901 can be performed simultaneously.

### Third Embodiment

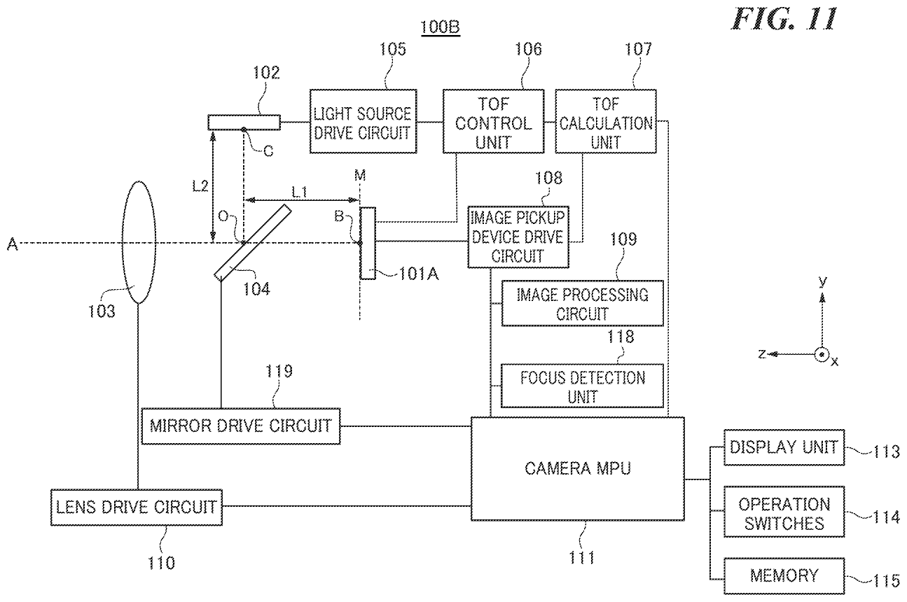

FIG. 11 is a block diagram showing a schematic configuration of an image pickup apparatus 100B according to a third embodiment. Among components of the image pickup apparatus 100B, the same reference numerals are assigned to the same components as those of the image pickup apparatus 100B according to the second embodiment, and descriptions thereof are omitted. In the image pickup apparatus 100 according to the second embodiment, the partial reflecting mirror 104 is fixed. However, the image pickup apparatus 100B includes a mirror drive circuit 119 which drives the partial reflecting mirror 104, which is different from the image pickup apparatus 100A.

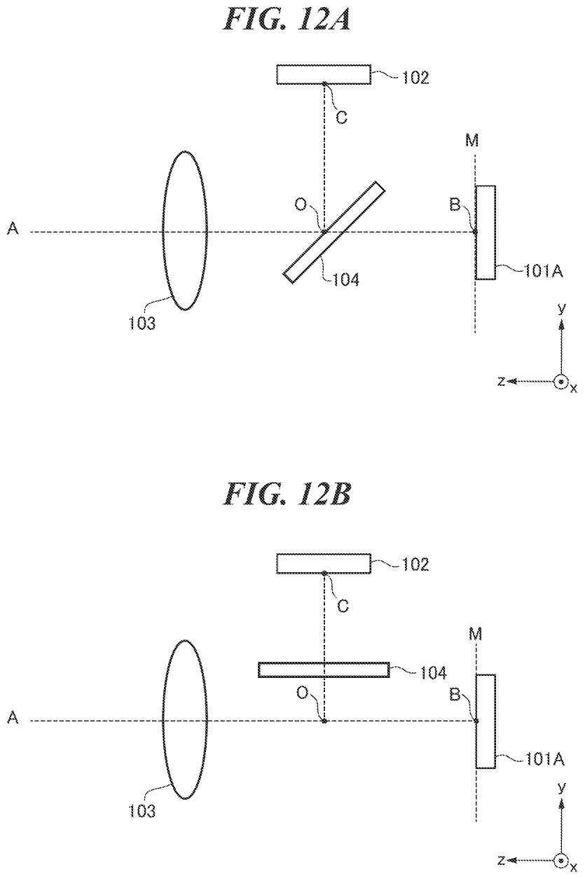

FIGS. 12A and 12B are diagrams schematically showing a driving mode of the partial reflecting mirror 104. FIG. 12A shows a state where the partial reflecting mirror 104 is at a down position (first position) in the optical path of the image-forming optical system 103. FIG. 12B shows a state where the partial reflecting mirror 104 is at an up position (second position) outside the optical path of the image-forming optical system 103. The partial reflecting mirror 104 is movable between the down position and the up position, and the mirror drive circuit 119 drives the partial reflecting mirror 104 according to a command from the camera MPU 111.

When creating the distance map of the subject by the TOF method and performing the focus adjustment by the image pickup surface phase difference method, the camera MPU 111 holds the partial reflecting mirror 104 at the down position by the mirror drive circuit 119. In other words, as described in the first and second embodiments, the partial reflecting mirror 104 reflects light emitted by the light source 102 to irradiate the subject at the down position, and guides the reflected light to the image pickup device 101A. As a result, the distance measurement by the TOF method is possible.

Meanwhile, when the partial reflecting mirror 104 is located at the down position during a main shooting (S611) by the image pickup device 101A, the amount of light incident on the image pickup device 101A decreases because a portion of the light is reflected by the partial reflecting mirror 104. Accordingly, image pickup sensitivity decreases. Therefore, the camera MPU 111 moves the partial reflecting mirror 104 to the up position during the main shooting by the mirror drive circuit 119 so that the incident light from the subject is directly incident on the image pickup device 101A. Thereby, the image pickup sensitivity can be increased.

### Fourth Embodiment

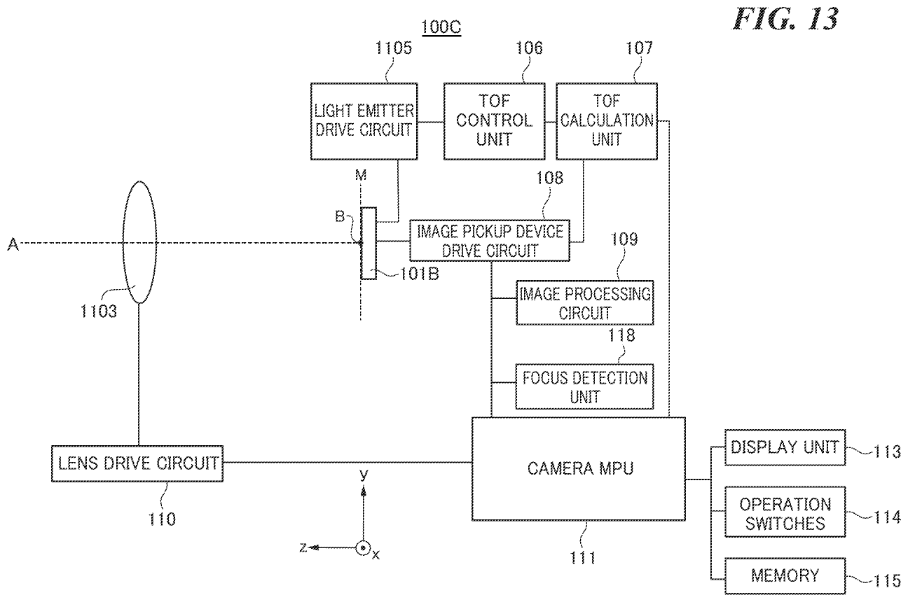

FIG. 13 is a block diagram showing a schematic configuration of an image pickup apparatus 100C according to the fourth embodiment.

The image pickup apparatus 100C is significantly different from the image pickup apparatus 100 according to the first embodiment in that the image pickup apparatus 100C does not include the partial reflecting mirror 104, the light source 102, and the light source drive circuit 105, and the image pickup device 101B includes light emitters described below and includes a light emitter drive circuit 1105 which drives the light emitters. It should be noted that among components of the image pickup apparatus 100C, the same reference numerals are assigned to the same components as those of the image pickup apparatus 100 according to the first embodiment, and common descriptions are omitted.

A main optical system of the image pickup apparatus 100C includes an image-forming optical system 1103 and an image pickup device 101B. A broken line AB shown in FIG. 13 indicates the central optical axis of the image-forming optical system 1103, and incident light from a subject located on the A side of the apparatus is formed into an image on the image pickup device 101B. The image-forming optical system 1103 is the same as the image-forming optical system 103 of the image pickup apparatus 100 according to the first embodiment except that the image-forming optical system 1103 does not have the partial reflecting mirror 104.

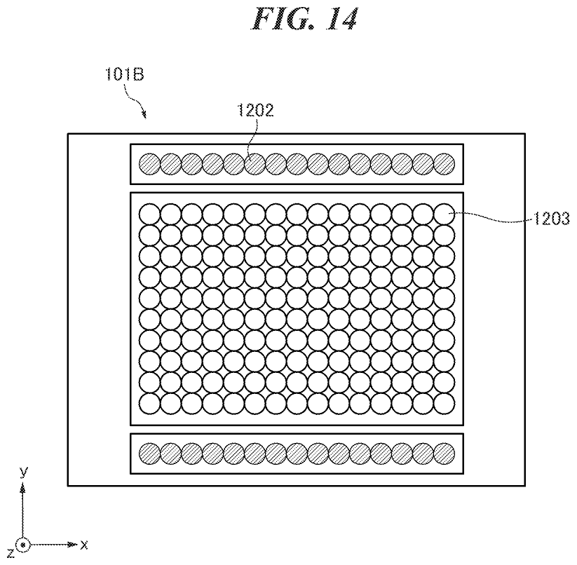

FIG. 14 is a diagram showing a schematic configuration of the image pickup device 101B. The image pickup device 101B has a structure in which a light receiving unit is disposed between light emitting units disposed at ends (upper and lower ends) facing in the y direction. The light emitting units each includes a plurality of light emitters 1202, and the light receiving unit includes a plurality of light receivers 1203. It should be noted that circles shown in FIG. 14 each represents microlenses provided on the light emitter 1202 and the light receiver 1203 on their light receiving surface side, respectively, and one light emitter 1202 has one microlens and one light receiver 1203 has one microlens.

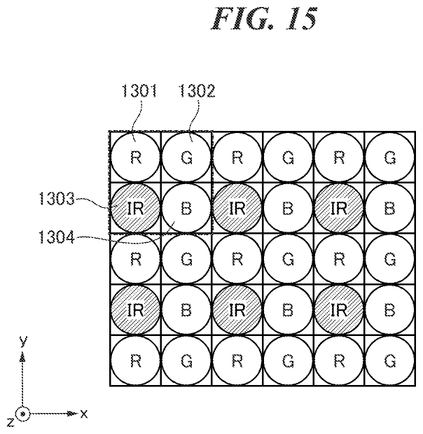

FIG. 15 is a diagram showing an array (pixel array) of the light receivers 1203 in the light receiving unit in the image pickup device 101B. In the image pickup device 101B, the light receivers 1203 which are periodically arranged two-dimensionally form an effective pixel region. For example, the image pickup device 101B is a CMOS sensor in which an effective pixel region has a horizontal size of 22.32 mm, a vertical size of 14.88 mm, an effective pixel number of 6000 in a horizontal direction, and an effective pixel number of 4000 in a vertical direction. The light receiver 1203 includes R pixels 1301 having high sensitivity to a wavelength of red light, G pixels 1302 having high sensitivity to a wavelength of green light, B pixels 1304 having high sensitivity to a wavelength of blue light, and IR pixels 1303 having high sensitivity to a wavelength of near-infrared light. That is, each of the R pixel 1301, the G pixel 1302, the B pixel 1304, and the IR pixel 1303 is a specific example of the light receiver 1203.

For example, the light emitter 1202 has a light emission part made of a gallium arsenide (GaAs) based compound semiconductor with a center emission wavelength of 850 nm. The light emitter drive circuit 1105 causes the light emitter 1202 to emit light according to a command from the camera MPU 111.

In the light emitting unit, the light emitters 1202 are arranged one-dimensionally and in the same plane along each of two facing sides on an outer periphery of the light receiving unit. Their light emission parts are, for example, light emitting diodes (LEDs), but are not limited thereto, and surface emitting lasers (VCSEL), stripe lasers, quantum dot elements, organic EL elements, or the like can also be used. Although light emitted by surface emitting lasers and many other small light emitters is divergent light, in the light emitter 1202, the divergent of light emitted by each light emission part is suppressed by a microlens.

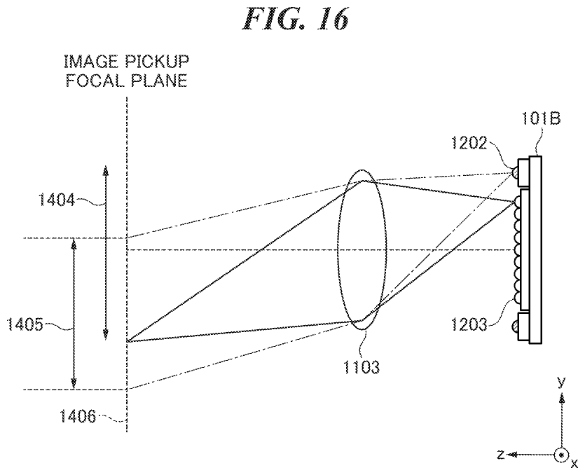

FIG. 16 is a diagram for explaining a relationship between the image pickup view angle given by the array of the light receivers 1203 and the light projection range of the light emitter 1202, based on the arrangement of the image-forming optical system 1103 and the image pickup device 101B on the yz plane. When an image pickup focal plane with respect to the array of the light receivers 1203 is represented by a broken line 1406, the microlenses of the light receivers 1203 of the image pickup device 101B and the image pickup focal plane are almost conjugate with each other via the image-forming optical system 1103. A certain point on the image pickup focal plane is formed into an image at a certain point of the light receiver 1203 of the image pickup device 101B, and this case, the image pickup view angle is represented by a range of an arrow 1404.

In the light emitters 1202, the distance between the light emission parts and the microlenses is set so that the projection region of light from the light emitters 1202 covers the image pickup view angle, and the light emitters 1202 and the image pickup focal plane do not have a conjugate relationship. In other words, the image pickup device 101B is designed such that the light emitted by the minute light emitters 1202 covers a wide area of the subject. Specifically, as shown in FIG. 16, the image pickup device 101B is designed such that a light projection region of light emitted by the light emitters 1202 disposed on the +y side of the image pickup device 101B covers a lower half or more in the y direction of the angle of view in the y direction. Although not shown, the light projection region of the light emitted by the light emitters 1202 disposed on the −y side of the image pickup device 101B covers an upper half or more in the y direction of the angle of view in the y direction. Therefore, the light emitters 1202 project light on the entire image pickup view angle, and thus, the IR pixels 1303 receive near-infrared light reflected from the subject.

It should be noted that the arrangement of the light emitter 1202 and the light receiver 1203 and/or the light projection region in the image pickup device 101B are not limited to the above-described configuration. For example, it may be designed so that light from the light emitters 1202 is projected on a desired area on which the distance measurement is to be performed, within the image pickup view angle. In particular, by setting an area equivalent to the image pickup view angle or an area inside the same to the light projection region, the light projection efficiency from the light emitter 1202 can be increased.

In a case where the focal length of the image-forming optical system 1103 is short or the F value is large, the amount of light from the light emitters 1202 per unit area on a surface at a certain distance from the image pickup device 101B decreases. Therefore, the light emitters 1202 that are changeable in the light emission intensity according to a change in the focal length or the F value is also one of the desirable configurations. By transmitting information on the focal length and/or F value of the image-forming optical system 1103 to the light emitter drive circuit 1105 from the image-forming optical system 1103 or the lens drive circuit (not shown) or the camera MPU 111 as needed, the distance measurement can be performed with an optimal amount of light. It should be noted that, here, the configuration in which the light emitters 1202 are disposed in one row is described, but a configuration in which the light emitters 1202 are replaced with a single light emission part is also possible.

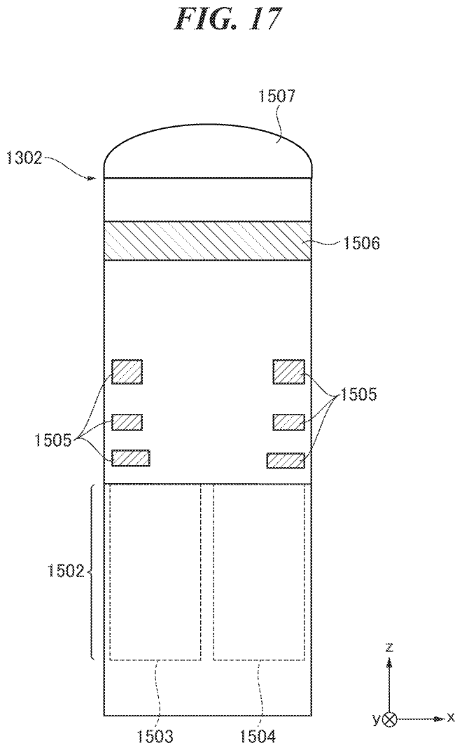

Each light receiver 1203 of the image pickup device 101B has a structure capable of performing the focus detection and the focus adjustment using a pupil division phase difference method. FIG. 17 is a diagram showing a schematic configuration of the G pixel 1302, which is one of the light receivers 1203, in a yz cross section. The photoelectric converter 1502 made of Si₅O₂ has sub photoelectric converters 1503, 1504 prepared by changing an impurity concentration partially by an ion implantation process, to perform pupil division of light entering thereto through the image-forming optical system 1103. An insulating part in which metal wiring layers 1505 are embedded is formed on the photoelectric converter 1502, and a color filter 1506 and a microlens 1507 are disposed in this order from the insulating part in the +z direction. It should be noted that the R pixels 1301, the B pixels 1304, and the IR pixels 1303 have different color filters from the G pixels 1302, but the other configurations are basically the same.

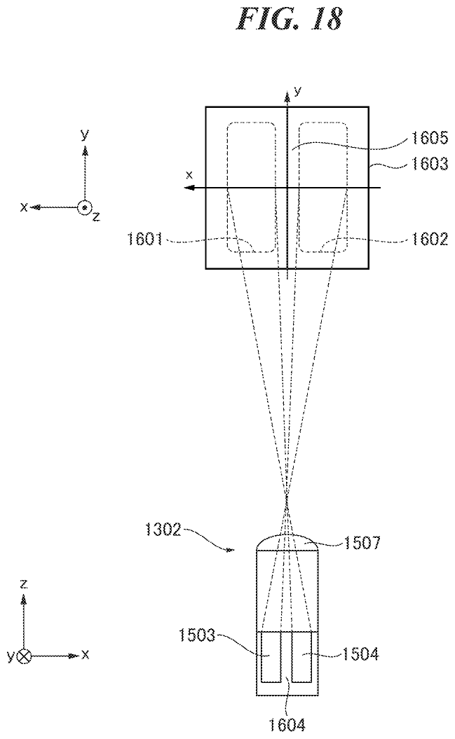

FIG. 18 is a diagram showing a relationship between the structure of the G pixel 1302 and the exit pupil plane 1603 of the image-forming optical system 1103, taking the G pixel 1302 as an example of the pixels. It should be noted that the exit pupil plane 1603 is a plane orthogonal to the optical axis (parallel to the z direction), and the cross section of the G pixel 1302 is a plane parallel to the optical axis.

The sub photoelectric converter 1503 corresponds to a first pupil division region 1602, the sub photoelectric converter 1504 corresponds to a second pupil division region 1601, and a separation part 1604 corresponds to a third pupil division region 1605. Therefore, in the incident light from the subject, light which has passed through the first pupil division region 1602 and light which has passed through the second pupil division region 1601 enter the sub photoelectric converter 1503 and the sub photoelectric converter 1504 via the microlens 1507, respectively. Moreover, light which has passed through the third pupil division region 1605 enters the separation part 1604 via the microlens 1507.

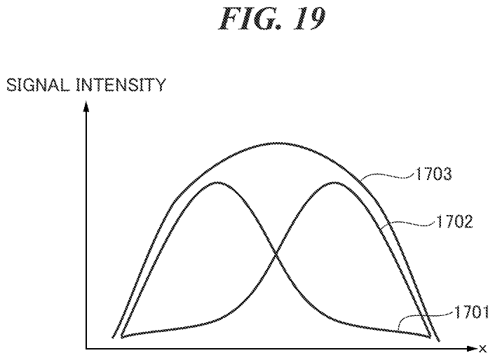

FIG. 19 is a diagram showing a distribution example of the signal intensities output from the sub photoelectric converters 1503 and 1504 and the signal intensity obtained by adding the signal intensities. The horizontal axis in FIG. 19 indicates x-coordinate values of the sub photoelectric converters 1503 and 1504 in FIG. 18, and the vertical axis indicates the signal intensities. The signal intensities 1701 and 1702 represent the signal intensities of the sub photoelectric converters 1503 and 1504, respectively, and the signal intensity 1703 represents the sum of the signal intensities 1701 and 1702.

Hereinafter, a subject image based on signals output from the sub photoelectric converters 1503 of respective pixels of the image pickup device 101B is referred to as an “A image”, and a subject image based on signals output from the sub photoelectric converters 1504 of respective pixels of the image pickup device 101B is referred to as a “B image”. Moreover, a subject image of signals obtained by adding the signal of the A image and the signal of the B image for each pixel is referred to as an “A+B image”. The image pickup device 101B can detect a defocus amount (a focus shift amount) of a subject image having a luminance distribution in the x direction, by detecting an image shift amount (relative position) between the A image and the B image.

The calculation of the image shift amount is given by, for example, shifting the relative position of the A image and the B image, obtaining the sum (reliability value) of squares of the differences between the A image signal and the B image signal for each pixel, and defining the shift amount from which the smallest reliability value has been defined as an image shift position. This is because the reliability value decreases, accuracy in the calculation of the image shift amount increases. As described above, in the image pickup apparatus 110C, the image pickup device 101B performs the focus detection by the pupil division phase difference method, and the lens drive circuit 110 drives lenses under the control of the camera MPU 111 based on the focus detection information. Accordingly, it enables the image pickup apparatus 110C to perform the focus adjustment by a phase difference method for adjusting the subject position and the focus position of the image-forming optical system 1103.

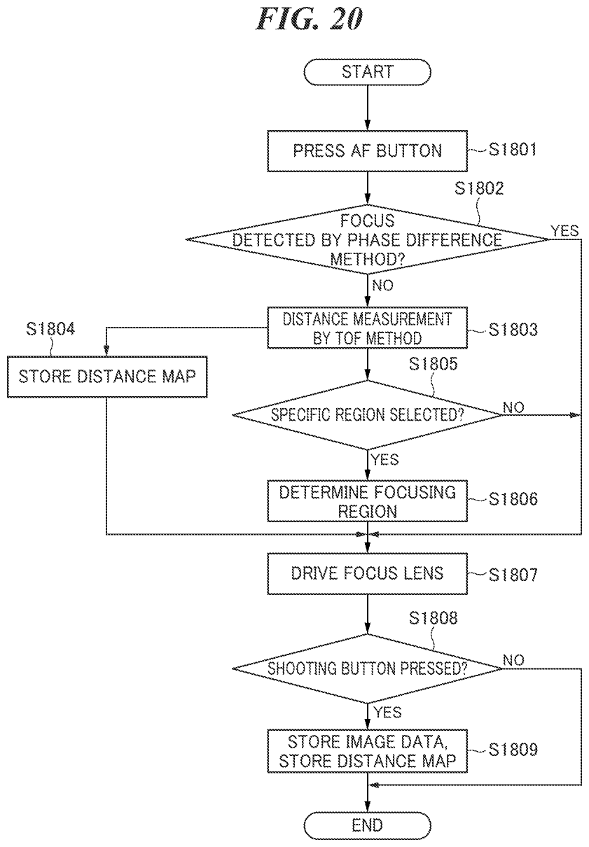

Next, an image pickup sequence in the image pickup apparatus 100C will be described. FIG. 20 is a flowchart showing the image pickup sequence in the image pickup apparatus 100C. Each processing (step) indicated by a symbol S in FIG. 20 is realized by the camera MPU 111 executing a predetermined program and totally controlling the operation of each unit of the image pickup apparatus 100.

In S1801, the camera MPU 111 detects that the AF button is pressed. It should be noted that the processing of S1801 is the same as the above-described S601. In S1802, the camera MPU 111 controls the focus detection unit 118, performs phase-difference-based focus detection processing by the pupil division phase difference method using the signal output from the image pickup device 101B, and determines whether or not the focus detection is possible. In a case where the camera MPU 111 determines that the focus is detected (YES in S1802), the processing proceeds to S1807, and in a case where the camera MPU 111 determines that the focus is not detected (NO in S1802), the processing proceeds to S1803.

In the case where the focus is not detected in S1802, the defocus on the subject is too large, and thus, in S1803, the camera MPU 111 performs the distance measurement by the TOF method. Specifically, a signal is transmitted from the TOF control unit 106 to the light emitter drive circuit 1105 through the camera MPU 111, and the light emitter drive circuit 1105 drives the light emitters 1202 included in the image pickup device 101B. The light emitters 1202 output periodic rectangular pulsed light with a center wavelength of 850 nm. The light projected onto the subject from the light emitter 1202 becomes partially reflected light or scattered light, passes through the image-forming optical system 1103 to enter the image pickup surface M of the image pickup device 101B, and is received by the IR pixels 1303.

In the image pickup apparatus 100C, as described above, the light projection region given by the group of light emitters 1202 is equivalent to the subject field region corresponding to the image pickup view angle of the group of light receivers 1203. Therefore, it is possible to reduce the wasted light which is projected outside the image pickup view angle, and thus, it is possible to increase light projection efficiency. In addition, the light receiving timing of IR pixels 1303 of the image pickup device 101B is that determined by a periodic rectangular pulse, and the image pickup device 101B thereby detects a time lag between a pulsed laser light from the light emitters 1202 and light received by the IR pixels 1303. The image pickup device 101B generates a detection signal of the detected time lag between the emitted light and the received light or a signal related thereto, and the TOF calculation unit 107 calculates the distance between the subject and the image pickup surface from the generated signal.

It should be noted that a method of detecting pulsed light emitted by the light emitters 1202 and the reflected light thereof, and a calculation of signals can use a known TOF method, and for example, can use a phase detection method of Hansard et al. described above. It should be noted that various techniques have been studied and proposed for the TOF method, and these techniques can be used in the present embodiment, and it is not necessary to use a specific technique in a limited manner.

When the distance measurement by the TOF method is performed in S1803, in S1804, the camera MPU 111 generates a distance map of the subject based on a result of the distance measurement by the TOF method in S1803, and stores the generated distance map in the internal memory of the camera MPU 111. After that, the camera MPU 111 advances the processing to S1807. Meanwhile, during the execution of S1803, a user can operate the touch panel provided on the display unit 113 of the image pickup apparatus 100C to select an arbitrary region in the image as a focusing region. Therefore, in S1805, the camera MPU 111 determines whether or not a specific region in the image is selected. In a case where the camera MPU 111 determines that the specific region is not selected (NO in S1805), the processing proceeds to S1807. In a case where the camera MPU 111 determines that the specific region is selected (YES in S1805), the processing proceeds to S1806. In S1806, the camera MPU 111 determines the region selected in S1805 as the focusing region.

In S1807, in a case where the processing is directly advanced from S1802 to S1807, the camera MPU 111 drives the focus lens constituting the image-forming optical system 1103 based on the focus detection information detected in S1802 to perform the focus adjustment (focusing). In addition, in S1807, in a case where the camera MPU 111 goes through S1804 or passes through a case where the determination in S1805 is NO, the camera MPU 111 drives the focus lens based on the distance map stored in S1804 to perform the focus adjustment (focusing). In S1807, in a case where the camera MPU 111 passes through the case where the determination in S1805 is NO, the camera MPU 111 drives the focus lens based on the distance map stored in S1804 and the focusing region determined in S1806 to perform the focus adjustment (focusing) on the focusing region. By driving the focus lens using the absolute distance information to the subject obtained by the TOF method, it is possible to perform the focus adjustment at high speed.

The processing of S1808 and S1809 is the same as the processing of S610 and S611 in the first embodiment, respectively. That is, in S1808, the camera MPU 111 determines whether the shooting button is pressed and the start of the shooting is instructed to the camera MPU 111. In a case where the camera MPU 111 determines that the shooting button is not pressed (NO in S1808), the camera MPU 111 determines that the user stops the shooting, and thus, the present processing ends. Meanwhile, in a case where the camera MPU 111 determines that the shooting button is pressed (YES in S1808), the processing proceeds to S1809.

In S1809, the camera MPU 111 stores the image data of a picked-up image and the distance map created in S1804 in a storage medium such as an SD card included in the memory 115, and thus, the present processing ends. It should be noted that the image data is generated using signals from the R pixels 1301, the G pixels 1302, and the B pixels 1304 of the image pickup device 101B, and the distance map is generated using signals from the IR pixels 1303.

In the image pickup apparatus 100C, it is desirable to change, according to the F value or the focal length of the image-forming optical system 1103, the light emission intensity of the light emitters 1202 in the focus detection by the TOF method. For example, in a case where the F value is large in the same shooting situation, the intensity of the light incident on the image pickup device 101B is small because an effective diameter of an imaging lens is small. Conversely, in a case where the F value is small in the same shooting situation, the intensity of the light incident on the image pickup device 101B is large. Accordingly, the intensities of the reflected light and the scattered light from the subject change according to the F value of the image-forming optical system 1103, which makes the TOF signal obtained by the light receiver 1203 unstable and decreases the detection accuracy decreases, or may lead a case where the detection is impossible. A similar problem may occur in a case where the size of the subject field changes according to the focal length of the image-forming optical system 1103 and the light projection intensity per unit solid angle of the image pickup view angle changes.

Therefore, to stably perform the TOF focus detection, the light emitters 1202 may be configured so that the light emission intensity thereof can be controlled by the TOF control unit 106 according to the F value, or the light emission intensity of the light emitters 1202 may be controlled according to the focal length of the image-forming optical system 1103. It should be noted that in a case where the received light intensity of the IR light by the image pickup device 101B is too small or too large in the first measurement by the TOF method, the light emitters 1202 may be controlled to correct the light projection intensity in the next measurement, which makes an image pickup sequence more desirable.

Meanwhile, in the image pickup sequence in the flowchart of FIG. 20, distance measurement by the TOF method is performed after the focus detection is performed by the pupil division phase difference method. However, the present invention is not limited to this, and the distance measurement by the TOF method may be performed first. In the focus detection of the pupil division phase difference method, a situation that the defocus is large or an environment visible high intensity is low, may make the focus detection difficult. In a case where it is difficult to detect the defocus amount, the camera MPU 111 needs to search for the focus position while moving the focus lens to a state where the defocus amount can be detected, and even if the driving of the focus lens for the search is performed, there is no guarantee that the focus can be detected. Further, a certain time is required for the driving for the search itself.

In this situation, the focus detection by the TOF method using the IR light which does not require visible light is effective, and it is preferable that the first focus detection in the drive sequence is performed by the TOF method. However, in the focus detection by the TOF method, in some cases, a distance resolution may be insufficient or the distance measurement accuracy may be low with respect to a subject field depth. Therefore, the camera MPU 111 preferably controls the focus detection unit 118 after the focus adjustment using the focus detection result by the TOF method to perform the focus detection by the pupil division phase difference method, and determines whether or not a state after the focus adjustment by the TOF method falls into a focusing range. As a result, the camera may go to the shooting operation when the state is the in-focus state, and may drive the focus lens again based on the focus detection result by the pupil division phase difference method when the state is the out-of-focus state so as to perform the focus adjustment.

Next, a variation of the image pickup device 101B will be described. In the image pickup apparatus 100C, the image pickup device 101B separately includes the light emitters 1202 and the light receivers 1203. Alternatively, an image pickup device including light receiving/emitting elements having both light receiving and light emitting functions may be used. In this case, in the in-focus state, light output from a light emission part of one pixel of the image pickup device reaches substantially one point on the subject, is reflected or scattered on the subject, goes back to be formed into an image on the original pixel again, and is received by a light receiving part. Accordingly, it is possible to perform the distance measurement by the TOF method using the light emission signal and the light reception signal. As a result, it is possible to increase a resolution of a distance measurement area by the TOF method.

For example, as the light receiving/emitting elements, light receiving/emitting elements (Japanese Laid-Open Patent Publication (kokai) No. S58-134483) focused on a light emitting/receiving function of LEDs, gallium nitride (GaN) based light receiving/emitting elements having a multiple quantum well structure, and light emitting and receiving elements using a nanorod are known. The light receiving/emitting elements having a multiple quantum well structure are disclosed in Y. Wang et al., Proc. SPIE 10823, Nanophotonics and Micro/Nano Optics IV, 108230H (25 Oct. 2018). The light receiving/emitting elements using a nanorod are disclosed in N. Oh et al., Science 355, 616 (2017) or the like, but light receiving/emitting elements to be used are not limited thereto.

### Fifth Embodiment

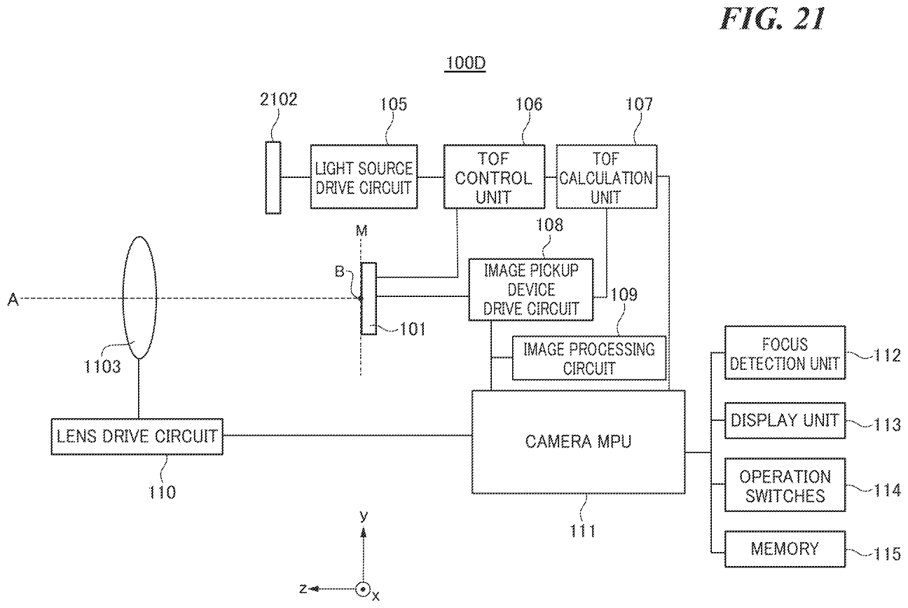

FIG. 21 is a block diagram showing a schematic configuration of an image pickup apparatus 100D according to a fifth embodiment.

The image pickup apparatus 100D is significantly different from the image pickup apparatus 100 according to the first embodiment in that the image pickup apparatus 100D does not include the partial reflecting mirror 104 and has a light source 2102 instead of the light source 102. Among components of the image pickup apparatus 100D, the same reference numerals are assigned to the same components as those of the image pickup apparatus 100 according to the first embodiment, and common descriptions are omitted. Further, since the image-forming optical system 1103 of the image pickup apparatus 100D is substantially the same as the image-forming optical system 1103 of the image pickup apparatus 100C according to the fourth embodiment, the same reference numerals are assigned, and descriptions thereof are omitted.

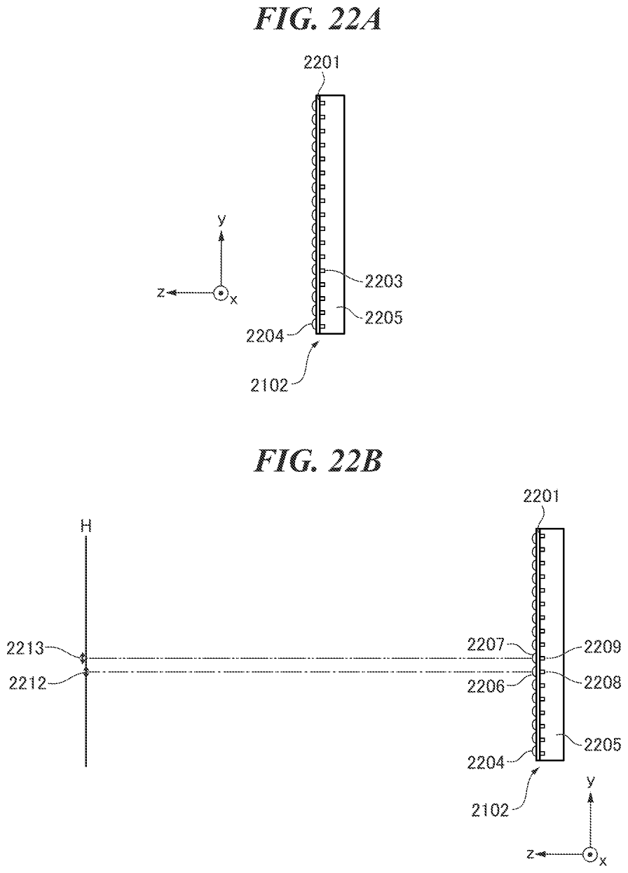

FIG. 22A is a side view explaining a schematic configuration of the light source 2102. The light source 2102 includes a plurality of light emission parts 2203 formed in a two-dimensional array on a gallium arsenide (GaAs) based semiconductor substrate 2205. Microlenses 2204 are disposed above the respective light emission parts 2203 in a two-dimensional array, and thus, a microlens array is formed. Each microlens 2204 collimates (or makes a divergence angle of light approaches 0°) the light from the corresponding light emission part 2203 or suppresses divergence of the light.

In the light source 2102, the microlens array is disposed on a distance control unit 2201 which can control the distance to the light emission parts 2203, so that emission conditions (emission state) of the light from the light emission parts 2203 can be changed according to an image pickup condition, as described later. It should be noted that the light source 2102 may be constituted by a single light emitter or light emission part.

In the light source 2102, surface emitting lasers (VCSELs) with a center emission wavelength of about 800 nm are used as the light emission parts 2203. A wavelength like an infrared light wavelength, being out of a visible light wavelength band that is used for pickup of a subject image by the image pickup device 101, is used for light to be emitted by the light source 2102, which enables an easy distinction between signals of distance measurement using the TOF method and signals of image pickup. It should be noted that the light emission parts 2203 are not limited to the above-described configuration, and for example, stripe lasers, light emitting diodes (LEDs), quantum dot elements, and organic EL elements can be used. Since light emitted by many minute light emitters including the surface emitting lasers is divergent light, the microlenses 2204 are disposed to suppress the divergence of divergent light from the light emission parts 2203.

FIG. 22B is a diagram showing light emitted by the light source 2102. Light from a light emission part 2208 located near the center of a light emitting surface of the light source 2102 and light from a light emission part 2209 adjacent thereto reach the subject position H with the divergence of light controlled by the corresponding microlenses 2206 and 2207. In this light source 2102, the emission direction of light is adjusted so that an area 2212 to which the light from the light emission part 2208 reaches and an area 2213 to which the light from the light emission part 2209 reaches do not greatly overlap with each other and are not greatly separated from each other. Such configuration enables even projection of light from the light source 2102 onto a required area at the subject distance H. Further, it keeps the light projection region for the subject area corresponding to the image pickup surface M of the image pickup device 101 constant, and the distance measurement can be performed with high light projection efficiency. The configuration can be realized by controlling the distance between the microlenses 2206 and 2207 and the light emission parts 2208 and 2209 by the distance control unit 2201. It should be noted that the image pickup view angle of the image pickup device 101 may be substantially equal to or larger than the light projection region.

The configuration of the light source 2102 is not limited to the above configuration. For example, by adjusting the emission direction so that the light emitted by the light emission parts 2203 is collimated, it enables the light source 2102 to project the light with sufficient intensity even in a case where the distance to the subject is long. In this case, in order to achieve projection of light by the light source 2102 with high efficiency in consideration of a manufacturing variation of the light source 102, the light source 2102 may be configured such that the light projection region exists slightly inside the subject area which can be picked up by the image pickup device 101.

When the focal length of the image-forming optical system 1103 is short or the F value is large, the amount of light from the light source 2102 per unit area on a plane located at a predetermined distance from the image pickup device 101 decreases. Therefore, the image pickup apparatus 100D may have the configuration so as to change the intensity of light emitted by the light source 2102 in accordance with a change in the focal length or the F value of the image-forming optical system 1103. The image-forming optical system 1103, the lens drive circuit 110, or the camera MPU 111 may transmit information on the focal length and the F value of the image-forming optical system 1103 to the light source drive circuit 105, as needed, as to change the intensity of the light emitted by the light source 2102. It enables the distance measurement with an appropriate amount of light.

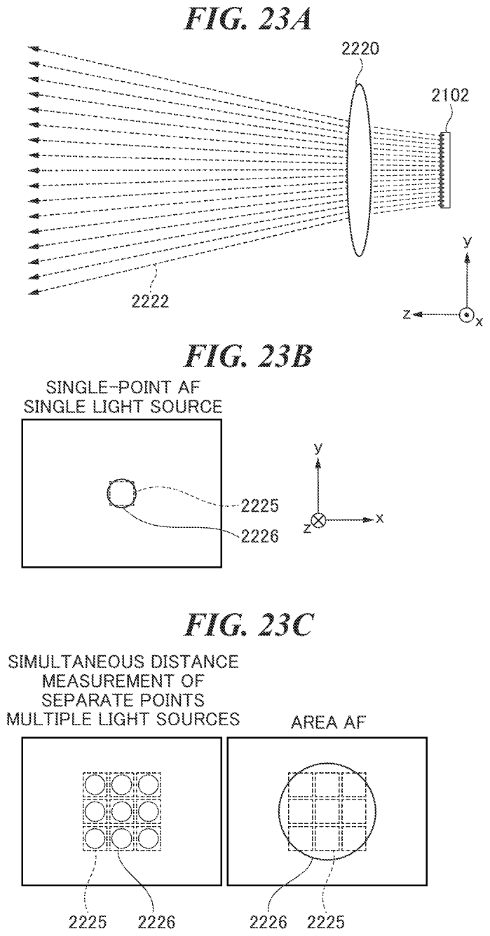

FIG. 23A is a diagram showing a configuration in which a control lens 2220 is disposed so as to cover light emitted by the light source 2102. In FIG. 23A, principal rays of light emitted by a plurality of light emission parts 2103 of the light source 2102 are schematically indicated by broken lines 2222. The control lens 2220 is disposed so as to be movable in the z direction, and controls a state in which light emitted by the light source 2102 is projected on the subject. For example, in a case where the image-forming optical system 1103 is constituted by a wide-angle lens having a short focal length, the position of the control lens 2220 is controlled so that the entire emitted light tends to diverge. Meanwhile, in a case where the image-forming optical system 1103 is constituted by a super-telephoto lens having a long focal length, a position of the control lens 2220 is controlled so that the entire emitted light is concentrated on the small area in order to achieve an image pickup in a small area at a long distance, and thus, high-efficiency light projection can be performed.

It should be noted that since the image pickup view angle changes according to the focal length of the image-forming optical system 1103, to control the degree of divergence or convergence of light emitted by the light source 2102, it is desirable to control the light source drive circuit 105 and the control lens 2220 so that the intensity of the emitted light per unit solid angle is constant. The camera MPU 111 controls the light source drive circuit 105 and the control lens 2220 so that an angle range in which the image-forming optical system 1103 can receive light and a angle range of projection light from the light source 2102 coincide with each other according to the focal length of the image-forming optical system 1103.

FIGS. 23B and 23C are diagrams each showing an example of a relationship between an AF frame 2225 and a light projection region 2226. FIG. 23B shows an example in a central single-point AF mode within an image pickup view angle, and FIG. 23C shows an example in a multi-point AF mode within the image pickup view angle. The AF frame 2225 indicated by broken lines is displayed on a display unit 113 like an electronic viewfinder or a liquid crystal monitor, the light projection region 2226 indicated by a circle is not actually displayed on the display unit 113, but is schematically shown for convenience of explanation.

In the image pickup apparatus 100D, it is desirable to change the light projection conditions to desired conditions according to a difference in the AF mode of the focus detection unit 112. For example, as shown in FIG. 23B, in the central single-point AF mode within the image pickup view angle, the light source 2102 is preferably controlled so as to project the emitted light to be selectively limited within an area corresponding to the AF frame, that is, so that the projection region of light from the light source 2102 to the subject is limited to a partial region of the subject. Further, as shown in a left diagram of FIG. 23C, in the multi-point distance measurement mode within the image pickup view angle, the light source 2102 is desirably controlled so as to project the emitted light to be selectively limited within an area corresponding to each AF frame. The change in the light emitting conditions can be made by the camera MPU 111, by selecting a light emission part which actually emits light from the light emission parts 2203, and, if necessary, controlling the distance between the microlenses 2204 and the light emission parts 2203 by the distance control unit 2201 and controlling the position of the control lens 2220. However, even in this case, it is desirable to adjust the light projection range according to the focal length and the subject distance. Moreover, even in the case of the multi-point distance measurement mode, when the subject distance is short, as shown in a right diagram of FIG. 23C, it is desirable to realize an area AF state in which the light is projected to an area including all of the multi-point AF frames in consideration of safety.

The image pickup device 101 is equivalent to the image pickup device 101 included in the image pickup apparatus 100 according to the first embodiment, and since configurations thereof and the like are described with reference to FIGS. 4A, 4B, 5A, and 5B, descriptions thereof are omitted.

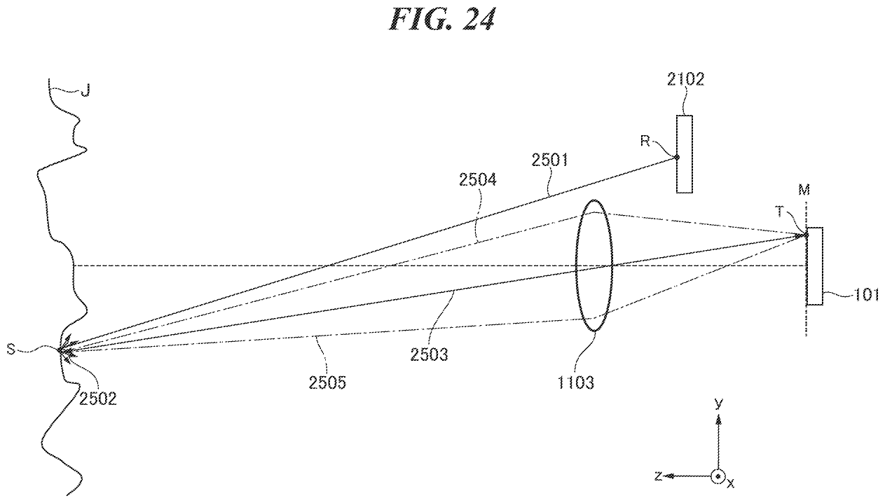

Next, an image pickup sequence in the image pickup apparatus 100D will be described. The image pickup sequence in the image pickup apparatus 100D can be executed according to the flowchart in FIG. 6 showing the image pickup sequence in the image pickup apparatus 100 according to the first embodiment. Therefore, here, the illustration of the flowchart and the overall description are omitted. However, since the methods of the distance measurement processing by the TOF method in S605 are different from each other between the image pickup apparatus 100D and the image pickup apparatus 100 according to the first embodiment, hereinafter, a distance measurement method by the TOF method in the image pickup apparatus 100D will be described below with reference to FIG. 24.

FIG. 24 is a diagram showing the distance measuring method by the TOF method in the image pickup apparatus 100D. The TOF control unit 106 transmits a signal to the light source drive circuit 105 through the camera MPU 111, and the light source drive circuit 105 drives the light source 2102. A periodic rectangular pulsed laser beam with a center wavelength of 800 nm is output from the light source 2102 toward a subject J.

Light (a ray at an optical center is indicated by a solid line 2501) emitted at a position R on an emission surface of the light source 2102 reaches a point S on the subject J. Light emitted by the light emission parts 2203 has a certain width, and scattered light 2502 including reflected light due to the emitted light is made at the point S on the subject J. A portion of the scattered light 2502 passes through an area (between dashed lines 2504 and 2505) where light passing through an opening of the image-forming optical system 1103 can pass through, and is formed into an image at a point T on the image pickup surface M of the image pickup device 101. It should be noted that in FIG. 24, a solid line 2503 indicates a ray passing through an approximate center between the dashed lines 2504 and 2505.

The image pickup apparatus 100D is configured such that the size and shape of an effective pixel area on the image pickup device 101 and the size and shape of an area where the light emission parts 2203 are arranged on the emission surface of the light source 2102 coincide with each other. Accordingly, there is less wasted light which is projected outside the image pickup view angle, and thus, it is possible to increase light projection efficiency. In addition, the light receiving timing of IR pixels (pixels 302) of the image pickup device 101 is that determined by a periodic rectangular pulse, and the image pickup device 101 thereby detects a time lag between light emitted by the light source 2102 and the received reflected light of the IR pixels and generates a detection signal or a signal related thereto. Then, the TOF calculation unit 107 calculates the distance between the point S on the subject J and the image pickup surface M from the generated signal. These operations are the method of the distance measurement processing by the TOF method in S605.

It should be noted that a method of detecting pulsed light emitted by the light source 2102 and the reflected light thereof, and a calculation of signals can use a known TOF method, and for example, can use a phase detection method of Hansard et al. described above. It should be noted that various techniques have been studied and proposed for the TOF method, and these techniques can be used in the present embodiment, and it is not necessary to use a specific technique in a limited manner.

### Sixth Embodiment

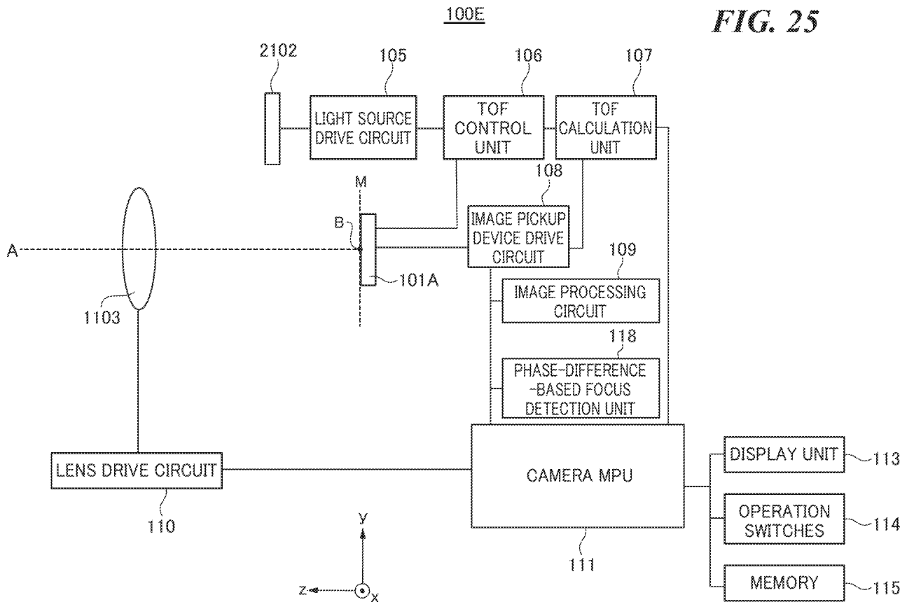

FIG. 25 is a block diagram showing a schematic configuration of an image pickup apparatus 100E according to the sixth embodiment.

In the image pickup apparatus 100E, the image pickup device 101 included in the image pickup apparatus 100D according to the fifth embodiment is changed to the image pickup device 101A included in the image pickup apparatus 100A according to the second embodiment, and the image pickup apparatus 100E includes a focus detection unit 118 associated therewith. Other configurations of the image pickup apparatus 100E are the same as those of the image pickup apparatus 100D. Therefore, among components of the image pickup apparatus 100E, the same reference numerals are assigned to the same components as those of the image pickup apparatus 100D according to the fifth embodiment and the image pickup apparatus 100 according to the first embodiment, and common descriptions are omitted.

As described in the second embodiment, the image pickup device 101A is an image pickup device capable of performing the focus detection using the image pickup surface phase difference method, the structure thereof is described with reference to FIG. 9, and thus, here, descriptions thereof are omitted.

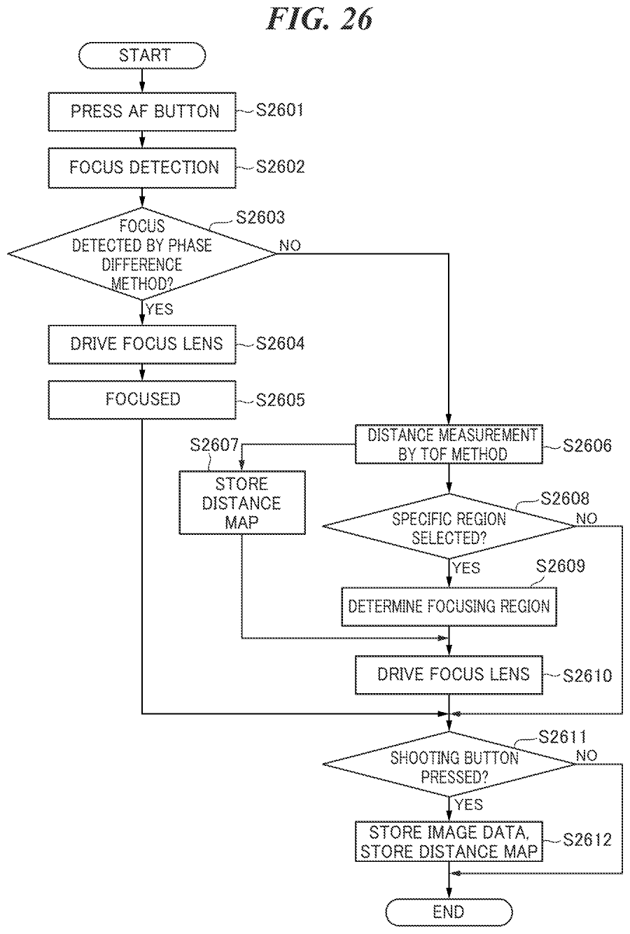

Next, an image pickup sequence in the image pickup apparatus 100E will be described. FIG. 26 is a flowchart showing the image pickup sequence in the image pickup apparatus 100E. Each processing (step) indicated by a symbol S in FIG. 26 is realized by the camera MPU 111 executing a predetermined program and totally controlling the operation of each unit of the image pickup apparatus 100E.

In S2601, the camera MPU 111 detects that the AF button is pressed. It should be noted that processing of S2601 is the same as that of S601 described above. In S2602, the camera MPU 111 controls the focus detection unit 118 to perform the focus detection processing by the image pickup surface phase difference method using the signal output from the image pickup device 101A. In S2603, the camera MPU 111 determines whether or not the focus detection is possible. In a case where the camera MPU 111 determines that the focus detection is possible (YES in S2603), the processing proceeds to S2604, and in a case where the camera MPU 111 determines that the focus detection is not possible (NO in S2603), the processing proceeds to S2606.

In S2604, the camera MPU 111 drives the lens drive circuit 110 based on the focus detection signal from focus detection unit 118 to move the focus lens in the optical axis direction. Accordingly, in S605, the MPU 111 can bring the image-forming optical system 1103 into the state in which the subject is focused (in focus), and thereafter, the processing proceeds to S2611.

In a case where the focus cannot be detected by the image pickup surface phase difference method, in S2606, the camera MPU 111 performs the distance measurement by the TOF method. Here, the distance measurement by the TOF method can be performed in the same manner as the distance measurement by the TOF method in the fifth embodiment, and detailed descriptions thereof are omitted. Moreover, the processing of S2606 to 52612 is performed in the same manner as the processing of S605 to S611 of the flowchart of FIG. 6 or the processing of S1803 to S1809 of the flowchart of FIG. 20 described as the image pickup sequence of the image pickup apparatus 100D according to the fifth embodiment. Therefore, here, descriptions of each processing are also omitted.

### OTHER EMBODIMENTS

Embodiments of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiments and/or that includes one or more circuits (e.g., application specific integrated circuit (ASIC)) for performing the functions of one or more of the above-described embodiments, and by a method performed by the computer of the system or apparatus by, for example, reading out and executing the computer executable instructions from the storage medium to perform the functions of one or more of the above-described embodiments and/or controlling the one or more circuits to perform the functions of one or more of the above-described embodiments. The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-084356, filed Apr. 25, 2019, and Japanese Patent Application No. 2020-028123, filed Feb. 21, 2020, which are hereby incorporated by reference wherein in its entirety.

What is claimed is:

1. An image pickup apparatus comprising:
an image pickup device;
a light source configured to emit pulsed light to a subject;
an image-forming optical system configured to guide light from the subject to the image pickup device;
at least one memory; and
at least one processor configured to execute instructions stored in the at least one memory to:
calculate, by a TOF method, a distance from the subject to an image pickup surface of the image pickup device using a signal output by the image pickup device receiving light emitted by the light source and reflected on the subject;
determine a condition for light emission of the light source according to a condition for pickup of an image of the subject; and
control light emission of the light source to the subject on a basis of the determined condition for light emission.

2. The image pickup apparatus according to claim 1, wherein
the light source comprises a plurality of light emitters, and
the image pickup apparatus further comprises an adjustment unit configured to adjust at least one of an emission direction of light from the light emitters and a projection state of light emitted by the light source to the subject.

3. The image pickup apparatus according to claim 1, wherein a light projection region of light emitted by the light source to the subject is narrower than an image pickup view angle of the image pickup device.

4. The image pickup apparatus according to claim 1, further comprising a changing unit configured to change an intensity of light output by the light source according to a focal length or an aperture value of the image-forming optical system.

5. The image pickup apparatus according to claim 1, wherein a wavelength band of light emitted by the light source is an infrared light wavelength band, and a wavelength band of light used to pick up an image of the subject by the image pickup device is a visible light wavelength band.

6. The image pickup apparatus according to claim 1, wherein the at least one processor executes instructions in the at least one memory to focus the image-forming optical system on the subject using distance information calculated by the at least one processor.

7. The image pickup apparatus according to claim 1, wherein
the image pickup device comprises a plurality of pixels each including a photoelectric converter including a first photoelectric converter and a second photoelectric converter, and
the image pickup apparatus further comprises a focus detector configured to use an image given by the first photoelectric converter and an image given by the second photoelectric converter to perform focus detection by an image pickup surface phase difference method.

8. The image pickup apparatus according to claim 7, wherein the at least one processor executes instructions in the at least one memory to focus the image-forming optical system on the subject using a focus detection result given by the focus detector, after focusing the image-forming optical system on the subject using distance information calculated by the at least one processor.

9. The image pickup apparatus according to claim 1, wherein the image-forming optical system is detachable from an image pickup apparatus body holding the image pickup device.

10. A method for controlling an image pickup apparatus, comprising:
projecting light from a light source to a subject;
upon the light being projected from the light source and reflected on the subject, calculating a distance from the subject to an image pickup surface of an image pickup device by a TOF method, using a signal output by the image pickup device receiving the light reflected on the subject;
generating a distance map from a result of calculation of the distance by the TOF method;
adjusting an image-forming optical system by using a result of calculation of the distance, to focus the image-forming optical system on a partially selected region of the subject;
performing image pickup on the subject with the image pickup device, with the image-forming optical system focused on the partially selected region; and
storing image data generated by the distance map and the image pickup in a storage unit.
